(19) United States
(12) Patent Application Publication
(10) Pub. No.: US 2026/0354077 A1
(43) Pub. Date: Nov. 5, 2026

(54) SUBSTRATE PROCESSING APPARATUS AND SUBSTRATE PROCESSING METHOD

(71) Applicant: SCREEN HOLDINGS CO., LTD., Kyoto (JP)

(72) Inventor: Shuhei NEMOTO, Kyoto (JP)

(21) Appl. No.: 19/108,119

(22) PCT Filed: Jul. 24, 2023
(86) PCT No.: PCT/JP2023/026933

§ 371 Date: Feb. 28, 2025

(30) Foreign Application Priority Data
Aug. 29, 2022 (JP) 2022-135572

(51) Int. Cl. H10P 72/00; B08B 9/28; H10P 52/00

(52) U.S. Cl. CPC H10P 72/0414; B08B 9/28; H10P 52/00; H10P 72/0431

(57) ABSTRACT

This invention relates to a substrate treatment technology that applies a predetermined substrate processing to a substrate by supplying a processing liquid to a substrate held in a rotating substrate holder, and collects liquid droplets of the processing liquid that are shaken off the substrate during the substrate processing. In this apparatus, while the rotating cup rotates about the axis of rotation, the cup rinsing liquid is supplied from the inside of the rotating cup directly to the rotating cup. This reduces the amount of cup rinsing liquid used while removing the processing liquid from the rotating cup to keep the rotating cup clean.

### TECHNICAL FIELD

This invention relates to a substrate processing apparatus and a substrate processing method for processing a substrate by supplying a processing liquid to the substrate. Herein, the substrate includes a semiconductor wafer, a glass substrate for liquid crystal display, a glass substrate for plasma display, an optical disk substrate, a magnetic disk substrate, a magneto-optical disk substrate, a glass substrate for photomask, a substrate for solar battery, and the like (hereinafter, referred to simply as a “substrate”). Further, the processing includes a bevel processing.

The disclosure of Japanese Patent Application No. 2022-135572 filed on Aug. 29, 2022 including specification, drawings and claims is incorporated herein by reference in its entirety.

### BACKGROUND

As a substrate processing apparatus which performs substrate processing such as chemical liquid processing or cleaning processing by supplying a processing liquid to a substrate such as a semiconductor wafer while rotating the substrate, an apparatus described in Patent Document 1 is known, for example. In this substrate processing apparatus, an outer cup is provided as a scattering preventing mechanism for receiving the processing liquid or the like scattered from the substrate rotated during the substrate processing. The outer cup is arranged in such a manner that an inner peripheral surface thereof surrounds an outer periphery of the rotated substrate while facing the outer periphery of the substrate. By doing so, liquid droplets of the processing liquid shaken off from the rotated substrate are collected in the outer cup.

### CITATION LIST

### Patent Literature

Patent Literature 1 Japanese Patent Application Laid Open Gazette No. 2017-92244

### SUMMARY

### Technical Problem

In this conventional apparatus, a base portion is provided with a plurality of cup cleaning nozzles for cleaning the inner peripheral surface of the outer cup. Furthermore, a cup cleaning member is arranged above the base portion. For cleaning the cup, a cleaning liquid (corresponding to one example of a “cup rinsing liquid” of the present invention) is supplied from the cup cleaning nozzles to the inner peripheral surface of the outer cup via a guide formed at the cup cleaning member. Hence, a large number of the cup cleaning nozzles are required to be provided for cleaning the inner peripheral surface of the outer cup entirely. Additionally, it is difficult for the cleaning liquid discharged from each cup cleaning nozzle toward the guide to be supplied entirely to the outer cup and the cleaning liquid may partially overflow from the guide. For these reasons, the cleaning liquid of a comparatively large amount is required for cleaning of the outer cup (corresponding to one example of “cup rinsing processing” of the present invention). Namely, the conventional substrate processing apparatus imposes a great deal of load on environment as a result of use of the cleaning liquid of a large amount, so that it has room for improvement in terms of reducing environmental load.

This invention is intended to solve the above-described problem, and it is an object of the present invention to provide a substrate processing apparatus and a substrate processing method capable of reducing environmental load by reducing the amount of use of a cup rinsing liquid required for cup rinsing processing.

### Solution to Problem

One aspect of this invention is directed to a substrate processing apparatus. The apparatus comprises: a substrate holder provided rotatably about an axis of rotation extending in a vertical direction while holding a substrate; a rotating cup provided rotatably about the axis of rotation while surrounding an outer periphery of the substrate held by the substrate holder; a rotating mechanism configured to rotate the substrate holder and the rotating cup; a processing mechanism configured to perform predetermined substrate processing on the substrate by supplying a processing liquid from a processing liquid discharge nozzle to the substrate held by the rotating substrate holder; a cup rinsing mechanism configured to perform cup rinsing processing of removing the processing liquid from the rotating cup by supplying a cup rinsing liquid from a side of the axis of rotation directly to the rotating cup where the processing liquid scattered from the substrate is collected; and a controller configured to control the rotating mechanism and the cup rinsing mechanism in such a manner as to supply the cup rinsing liquid to the rotating cup while rotating the rotating cup after implementation of the substrate processing.

Other aspect of the invention is a substrate processing method. The method comprises: a step of performing predetermined substrate processing on a substrate configured to rotate about an axis of rotation extending in a vertical direction with a processing liquid by supplying the processing liquid to the substrate while surrounding an outer periphery of the substrate with a rotating cup, and collecting the processing liquid scattered from the substrate in the rotating cup; and cup rinsing of removing the processing liquid from the rotating cup by supplying a cup rinsing liquid from a side of the axis of rotation directly to the rotating cup while rotating the rotating cup about the axis of rotation with the processing liquid collected in the rotating cup.

According to the invention having the foregoing configuration, while the rotating cup rotates about the axis of rotation with the processing liquid collected therein, the cup rinsing liquid is supplied from the inside of the rotating cup directly to the rotating cup. This allows the amount of use of the cup rinsing liquid to be reduced significantly compared to the amount used in the substrate processing apparatus described in Patent Document 1.

### Advantageous Effects of Invention

As described above, according to the present invention, it is possible to reduce environmental load by reducing the amount of use of the cup rinsing liquid required for cup rinsing of the rotating cup where the processing liquid scattered from the substrate is collected.

All of a plurality of constituent elements of each aspect of the invention described above are not essential and some of the plurality of constituent elements can be appropriately changed, deleted, replaced by other new constituent elements or have limited contents partially deleted in order to solve some or all of the aforementioned problems or to achieve some or all of effects described in this specification. Further, some or all of technical features included in one aspect of the invention described above can be combined with some or all of technical features included in another aspect of the invention described above to obtain one independent form of the invention in order to solve some or all of the aforementioned problems or to achieve some or all of the effects described in this specification.

### BRIEF DESCRIPTION OF DRAWINGS

FIG. 1 is a plan view showing a schematic configuration of a substrate processing system equipped with a first embodiment of a substrate processing apparatus according to the invention.

FIG. 2 is a diagram showing a configuration of the first embodiment of the substrate processing apparatus according to the invention.

FIG. 3 is a diagram schematically showing a configuration of a chamber and a configuration attached to the chamber.

FIG. 4 is a plan view schematically showing the configuration of the substrate processing part installed on the base member.

FIG. 5 is a plan view schematically showing the configuration of the substrate processing part installed on the base member.

FIG. 6 is a diagram partially showing a rotating cup and a fixed cup.

FIG. 7 is an external perspective view showing a configuration of an upper surface protecting/heating mechanism.

FIG. 8 is a sectional view of the upper surface protecting/heating mechanism shown in FIG. 7.

FIG. 9 is a perspective diagram showing the processing liquid discharge nozzle on the upper surface side provided at the processing mechanism and a cup rinsing liquid discharge nozzle on the upper surface side provided at the cup rinsing mechanism.

FIG. 10 is a diagram schematically showing a configuration of the nozzle mover.

FIG. 11A is a schematic diagram showing a nozzle position for implementation of the bevel processing.

FIG. 11B is a schematic diagram showing a nozzle position for implementation of cup rinsing processing.

FIG. 12 is a perspective diagram showing the lower surface side processing liquid discharge nozzle and the nozzle support that supports the same nozzle, both of which are equipped in the processing mechanism.

FIG. 13 is a flowchart showing bevel processing performed, as an example of a substrate processing operation, by the substrate processing apparatus shown in FIG. 2.

FIG. 14 is a diagram schematically showing the configuration and operation of the second embodiment of the substrate processing apparatus according to the present invention.

### DESCRIPTION OF EMBODIMENTS

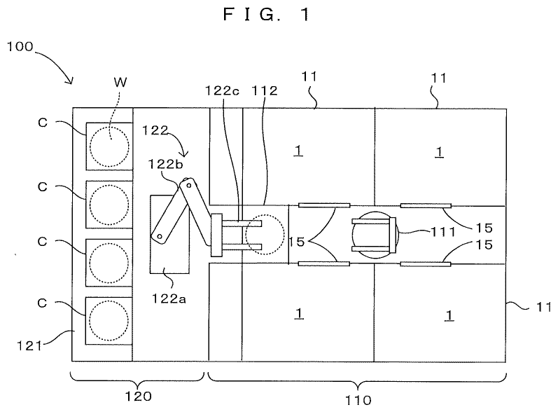

FIG. 1 is a plan view showing a schematic configuration of a substrate processing system equipped with a first embodiment of a substrate processing apparatus according to the invention. This figure is a diagram not showing the external appearance of the apparatus, but showing an internal structure of a substrate processing system 100 by excluding an outer wall panel and other partial configurations. This substrate processing system 100 is, for example, a single-wafer type apparatus installed in a clean room and configured to process substrates W each having a circuit pattern (hereinafter, referred to as a “pattern”) only on one principal surface one by one. Then, substrate processing using a processing liquid is performed in a processing unit 1 equipped in the substrate processing system 100. In this specification, a pattern formation surface (one principal surface) formed with the pattern is referred to as a “front surface” and the other principal surface not formed with the pattern on an opposite side is referred to as a “back surface”. Further, a surface facing down is referred to as a “lower surface” and a surface facing up is referred to as an “upper surface”. Further, in this specification, the “pattern formation surface” means a surface of the substrate where an uneven pattern is formed in an arbitrary region regardless of whether the surface is flat, curved or uneven.

Here, various substrates such as semiconductor wafers, glass substrates for photomask, glass substrates for liquid crystal display, glass substrates for plasma display, substrates for FPD (Flat Panel Display), optical disk substrates, magnetic disk substrates and magneto-optical disk substrates can be applied as the “substrate” in the present embodiment. Although the substrate processing apparatus used in processing semiconductor wafers is mainly described as an example with reference to the drawings below, application to the processing of various substrates illustrated above is also possible.

As shown in FIG. 1, the substrate processing system 100 includes a substrate processing station 110 for processing the substrate W and an indexer station 120 coupled to this substrate processing station 110. The indexer station 120 includes a container holder 121 capable of holding a plurality of containers C for housing the substrates W (FOUPs (Front Opening Unified Pods), SMIF (Standard Mechanical Interface) pods, OCs (Open Cassettes) for housing a plurality of the substrates W in a sealed state), and an indexer robot 122 for taking out an unprocessed substrate W from the container C by accessing the container C held by the container holder 121 and housing a processed substrate W in the container C. A plurality of the substrates W are housed substantially in a horizontal posture in each container C.

The indexer robot 122 includes a base 122a fixed to an apparatus housing, an articulated arm 122b provided rotatably about a vertical axis with respect to the base 122a, and a hand 122c mounted on the tip of the articulated arm 122b. The hand 122c is structured such that the substrate W can be placed and held on the upper surface thereof. Such an indexer robot including the articulated arm and the hand for holding the substrate is not described in detail since being known.

The substrate processing station 110 includes a mounting table 112 on which the indexer robot 122 places the substrate W, a substrate conveyor robot 111 arranged substantially in a center in a plan view and a plurality of processing units 1 arranged to surround this substrate conveyor robot 11. Specifically, the plurality of processing units 1 are arranged to face a space where the substrate conveyor robot 111 is arranged. The substrate conveyor robot 111 randomly accesses the mounting table 112 for these processing units 1 and transfers the substrate W to and from the mounting table 112. On the other hand, each processing unit 1 performs a predetermined processing to the substrate W, and corresponds to the substrate processing apparatus according to the present invention. In the present embodiment, these processing units (substrate processing apparatus) 1 have the same function. Thus, a plurality of the substrates W can be processed in parallel. If the substrate conveyor robot 111 can directly transfer the substrate W from the indexer robot 122, the mounting table 112 is not necessarily required.

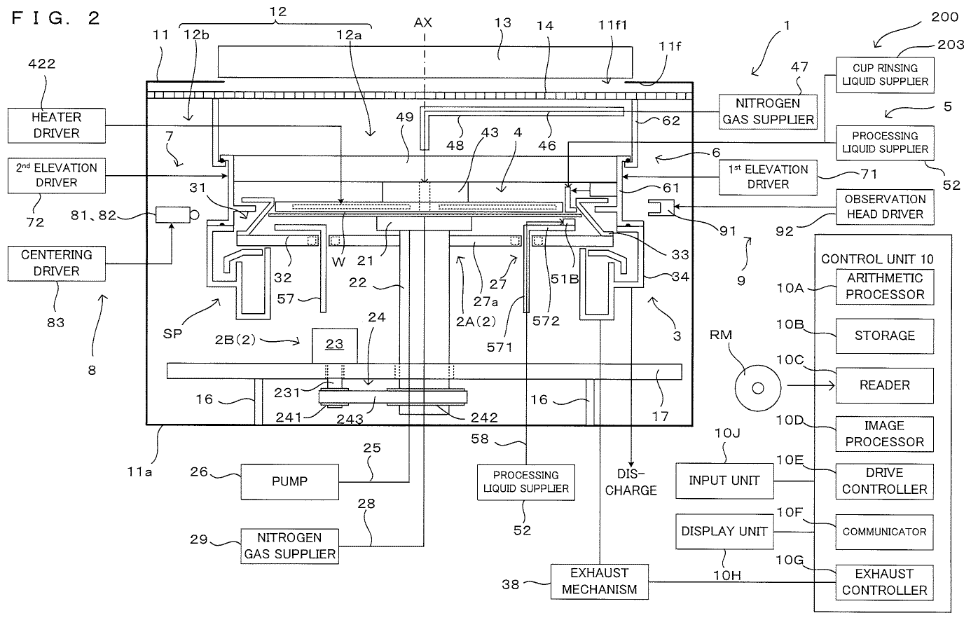

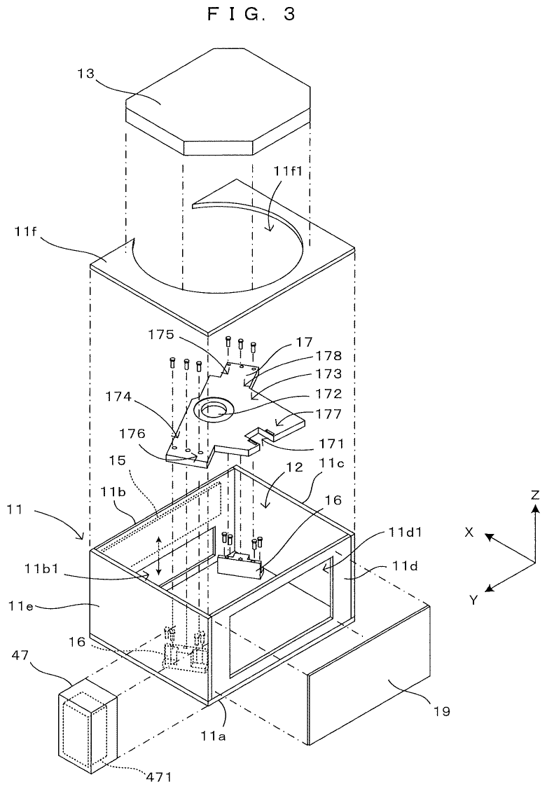

FIG. 2 is a diagram showing a configuration of the first embodiment of the substrate processing apparatus according to the invention. Further, FIG. 3 is a diagram schematically showing a configuration of a chamber and a configuration attached to the chamber. In FIGS. 2 and 3 and each figure to be referred to below, the dimensions and numbers of respective components may be shown in an exaggerated or simplified manner to facilitate understanding. As shown in FIG. 3, a chamber 11 used in the substrate processing apparatus (processing unit) 1 has a bottom wall 11 a having a rectangular shape in a plan view vertically from above, four sidewalls 11b to 11e standing from a periphery of the bottom wall 11a, and a ceiling wall 11f covering respective upper end parts of the sidewalls 11b to 11e. By combining the bottom wall 11a, the sidewalls 11b to 11e, and the ceiling wall 11f, formed is an internal space 12 having a substantially rectangular parallelopiped shape.

On an upper surface of the bottom wall 11a, base support members 16 and 16 are fixed away from each other by fastener components such as bolts or the like. Specifically, the base support member 16 stands from the bottom wall 11a. On respective upper end parts of these base support members 16 and 16, a base member 17 is fixed by the fastener components such as bolts or the like. This base member 17 has a plane size smaller than that of the bottom wall lla and is composed of a metal plate having a thickness larger than that of the bottom wall 11a and rigidity higher than that thereof. As shown in FIG. 2, the base member 17 is raised by the base support members 16 and 16 from the bottom wall lla vertically upward. In other words, a so-called raised floor structure is formed on a bottom part of the internal space 12 of the chamber 11. As described later, an upper surface of this base member 17 is finished to allow a substrate processing part SP for performing substrate processing on the substrate W to be installed thereon, and the substrate processing part SP is installed on the upper surface thereof. Components constituting this substrate processing part SP are electrically connected to a control unit 10 for controlling the entire apparatus and operate in response to commands from the control unit 10. Further, the shape of the base member 17 and the configuration and operation of the substrate processing part SP will be described in detail.

As shown in FIGS. 2 and 3, a fan filter unit (FFU) 13 is attached to a ceiling wall 11f of the chamber 11. This fan filter unit 13 further cleans air in a clean room in which the substrate processing apparatus 1 is installed, and supplies the cleaned air into an internal space 12 of the chamber 11. The fan filter unit 13 includes a fan and a filter (e.g. a HEPA (High Efficiency Particulate Air) filter) for taking in the air in the clean room and feeding the air into the chamber 11, and feeds the cleaned air via an opening 11f1 provided in the ceiling wall 11f. In this way, a downflow of the cleaned air is formed in the internal space 12 in the chamber 11. Further, a punching plate 14 perforated with a multitude of air outlets is provided right below the ceiling wall 11f to uniformly disperse the cleaned air supplied from the fan filter unit 13.

As shown in FIG. 3, in the substrate processing apparatus 1, a conveyance opening 11b1 is provided in the sidewall 11b facing the substrate conveyor robot 111 among the four sidewalls 11b to lle, and the internal space 12 communicates with the outside of the chamber 11 therethrough. For this reason, a hand (not shown) of the substrate conveyor robot 111 can access the substrate processing part SP through the conveyance opening 11b1. In other words, by providing the conveyance opening 11b1, the substrate W can be loaded into or unloaded from the internal space 12. Further, a shutter 15 for opening and closing this conveyance opening 11b1 is attached to the sidewall 11b.

A shutter opening/closing mechanism (not shown) is connected to the shutter 15, and opens or closes the shutter 15 in response to an opening/closing command from the control unit 10. More specifically, in the substrate processing apparatus 1, the shutter opening/closing mechanism opens the shutter 15 in carrying an unprocessed substrate W into the chamber 11, and the unprocessed substrate W is carried in a face-up posture to the substrate processing part SP of the rotating mechanism 2 by a hand of a substrate conveyor robot 111. That is, the substrate W is placed on the spin chuck 21 with an upper surface Wf facing up. If the hand of the substrate conveyor robot 111 is retracted from the chamber 11 after the substrate W is carried into, the shutter opening/closing mechanism closes the shutter 15. Then, a bevel processing is performed on the peripheral edge part Ws of the substrate W, as an example of a “substrate processing” of the invention by the substrate processing part SP, in the processing space (equivalent to a sealed space SPs to be described in detail later) of the chamber 11. Further, after the bevel processing is finished, the shutter opening/closing mechanism opens the shutter 15 again and the hand of the substrate conveyor robot 111 carries out the processed substrate W from the substrate processing part SP. As just described, in the present embodiment, the internal space 12 of the chamber 11 is kept in a normal temperature atmosphere. Note that the “normal temperature” means a temperature in a range of 5 °C to 35 °C in this specification.

As shown in FIG. 3, the sidewall 11d is positioned on the opposite side of the sidewall 11b with respect to the substrate processing part SP (FIG. 2) installed on the base member 17. In this sidewall 11 d, provided is a maintenance opening 11d1. During maintenance, as shown in this figure, the maintenance opening 11d1 is opened. For this reason, an operator can access the substrate processing part SP through the maintenance opening 11d1 from the outside of the apparatus. On the other hand, during the substrate processing, a lid member 19 is so attached as to close the maintenance opening 11d1. Thus, in the present embodiment, the lid member 19 is detachable from the sidewall 11d.

Further, on an outer surface of the sidewall lle, a heated gas supplier 47 for supplying the substrate processing part SP with a heated inert gas (nitrogen gas in the present embodiment) is attached. This heated gas supplier 47 incorporates a heater 471.

Thus, on the outer wall side of the chamber 11, the shutter 15, the lid member 19, and the heated gas supplier 47 are arranged. In contrast to this, in an inner side of the chamber 11, i.e., in the internal space 12, the substrate processing part SP is installed on the upper surface of the base member 17 having the raised floor structure. Hereinafter, with reference to FIGS. 2 to 13, the configuration of the substrate processing part SP will be described.

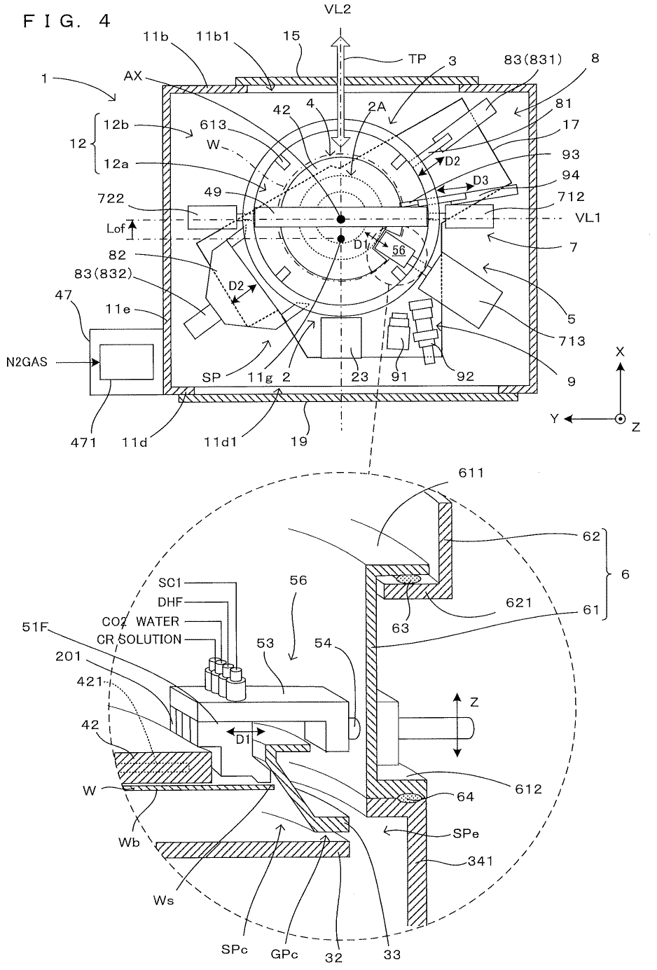

FIG. 4 is a plan view schematically showing the configuration of the substrate processing part installed on the base member. Hereinafter, for clarifying the arrangement relation and operation of the components of the apparatus, a coordinate system with a Z direction as a vertical direction and with an XY plane as a horizontal plane is shown as appropriate. In the coordinate system of FIG. 4, it is assumed that a horizontal direction in parallel to a convey ance path TP of the substrate W is an “X direction” and a horizontal direction orthogonal to the X direction is a “Y direction”. In more detail, directions from the internal space 12 of the chamber 11 toward the conveyance opening 11b1 and the maintenance opening 11d1 are referred to as a “+X direction” and a “−X direction”, respectively, directions from the internal space 12 of the chamber 11 toward the sidewalls 11c and 11e are referred to as a “−Y direction” and a “+Y direction”, respectively, and directions vertically upward and downward are referred to as a “+Z direction” and a “−Z direction”, respectively. In the same figure, “CR solution” means cup rinsing liquid.

The substrate processing part SP includes a holding/rotating mechanism 2, a scattering preventing mechanism 3, an upper surface protecting/heating mechanism 4, a processing mechanism 5, an atmosphere separating mechanism 6, an elevating mechanism 7, a centering mechanism 8, and a substrate observing mechanism 9 and a cup rinsing mechanism. These mechanisms are provided on the base member 17. Specifically, with reference to the base member 17 having rigidity higher than that of the chamber 11, the holding/rotating mechanism 2, the scattering preventing mechanism 3, the upper surface protecting/heating mechanism 4, the processing mechanism 5, the atmosphere separating mechanism 6, the elevating mechanism 7, the centering mechanism 8, the substrate observing mechanism 9 and the cup rinsing mechanism are arranged to one another with a positional relation determined in advance.

As shown in FIG. 2, the holding/rotating mechanism 2 includes a substrate holder 2A for holding the substrate W substantially in a horizontal posture with a surface of the substrate W facing up and a rotating mechanism 2B for synchronously rotating the substrate holder 2A holding the substrate W and part of the scattering preventing mechanism 3. For this reason, when the rotating mechanism 2B operates in response to a rotation command from the control unit 10, the substrate W and a rotating cup 31 of the scattering preventing mechanism 3 are rotated about an axis of rotation AX extending in parallel to the vertical direction Z.

The substrate holder 2A includes the spin chuck 21 which is a disk-like member smaller than the substrate W. The spin chuck 21 is so provided that an upper surface thereof is substantially horizontal and a center axis thereof coincides with the axis of rotation AX. Especially in the present embodiment, as shown in FIG. 4, a center of the substrate holder 2A (which corresponds to the center axis of the spin chuck 21) is offset in the (+X) direction relative to a center 11g of the chamber 11. Specifically, the substrate holder 2A is arranged so that the center axis (axis of rotation AX) of the spin chuck 21 may be positioned at a processing position deviated from the center 11g of the internal space 12 toward a side of the conveyance opening 11b1 by a distance Lof in a plan view of the chamber 11 viewed from above. Further, for clarifying the later-described arrangement relation of the components of the apparatus, in the present specification, a virtual line passing through the center (axis of rotation AX) of the substrate holder 2A which is offset and being orthogonal to the conveyance path TP and another virtual line in parallel to the conveyance path TP are referred to as a “first virtual horizontal line VL1” and a “second virtual horizontal line VL2”, respectively.

A cylindrical rotary shaft 22 is coupled to a lower surface of the spin chuck 21. The rotary shaft 22 extends in the vertical direction Z with an axis line thereof coinciding with the axis of rotation AX. Further, the rotating mechanism 2B is connected to the rotary shaft 22.

The rotating mechanism 2B has a motor 23 which generates a rotational driving force for rotating the substrate holder 2A and the rotating cup 31 of the scattering preventing mechanism 3 and a power transmitter 24 for transmitting the rotational driving force. The motor 23 has a rotation shaft 231 rotating with generation of the rotational driving force. The motor 23 is provided at a motor attachment portion 171 of the base member 17 in a posture with the rotation shaft 231 extending vertically downward. In more detail, as shown in FIG. 3, the motor attachment portion 171 is a portion which is cut out in the (+X) direction while facing the maintenance opening 11d1. A cutout width (size in the Y direction) of this motor attachment portion 171 is almost equal to the width of the motor 23 in the Y direction. For this reason, the motor 23 is movable in the X direction with a side surface thereof engaged with the motor attachment portion 171.

The motor 23 is fixed to the base member 17 while being positioned in the X direction with the motor attachment portion 171. At a tip part of the rotation shaft 231 protruding downward from the base member 17, attached is a first pulley 241. At a lower end part of the substrate holder 2A, attached is a second pulley 242. In more detail, the lower end part of the substrate holder 2A is inserted into the through hole provided in a spin chuck attachment portion 172 of the base member 17 and protrudes downward from the base member 17. This protruding portion is provided with the second pulley 242. Then, an endless belt 243 is put over between the first pulley 241 and the second pulley 242. Thus, in the present embodiment, the first pulley 241, the second pulley 242, and the endless belt 243 constitute the power transmitter 24.

A through hole (not shown) is provided at a central part of the spin chuck 21 and communicates with an internal space of the rotary shaft 22. A pump 26 is connected to the internal space via a pipe 25 having a valve (not shown) disposed therein. This pump 26 and the valve are electrically connected to the control unit 10 and operate in response to a command from the control unit 10. In this way, a negative pressure and a positive pressure are selectively applied to the spin chuck 21. If the pump 26 applies a negative pressure to the spin chuck 21, for example, with the substrate W placed substantially in a horizontal posture on the upper surface of the spin chuck 21, the spin chuck 21 sucks and holds the substrate W from below. On the other hand, if the pump 26 applies a positive pressure to the spin chuck 21, the substrate W can be taken out from the upper surface of the spin chuck 21. Further, if the suction of the pump 26 is stopped, the substrate W is horizontally movable on the upper surface of the spin chuck 21.

A nitrogen gas supplier 29 is connected to the spin chuck 21 via a pipe 28 provided in a central part of the rotary shaft 22. The nitrogen gas supplier 29 supplies a nitrogen gas at a normal temperature supplied from a utility of a factory, in which the substrate processing system 100 is installed, to the spin chuck 21 at a flow rate and a timing corresponding to a nitrogen gas supply command from the control unit 10, and causes the nitrogen gas to flow from the central part to a radially outer side on the side of a lower surface Wb of the substrate W. Note that although the nitrogen gas is used in the present embodiment, another inert gas may be used. This point also applies to a heated gas discharged from a central nozzle to be described later. Further, the “flow rate” means a moving amount of a fluid such as the nitrogen gas per unit time.

The rotating mechanism 2B includes a power transmitter 27 (FIG. 2) for not only rotating the spin chuck 21 integrally with the substrate W, but also rotating the rotating cup 31 in synchronization with the former rotation. The power transmitter 27 includes an annular member 27a (FIG. 2) made of a non-magnetic material or resin, spin chuck side magnets (not shown) built-in the annular member 27a, and cup side magnets (not shown) built-in a lower cup 32, which is one component of the rotating cup 31. The annular member 27a is attached to the rotary shaft 22 and rotatable about the axis of rotation AX together with the rotary shaft 22. More particularly, the rotary shaft 22 includes a flange part 22a protruding radially outward at a position right below the spin chuck 21 as shown in FIG. 2. The annular member 27a is arranged concentrically with respect to the flange part (not shown), and coupled and fixed by an unillustrated bolt or the like.

A plurality of spin chuck side magnets are arranged radially and at equal angular intervals (10° in the present embodiment) with the axis of rotation AX as a center on an outer peripheral edge part of the annular member 27a. In the present embodiment, an N-pole and an S-pole are respectively arranged on an outer side and an inner side of one of the two spin chuck side magnets adjacent to each other, and an S-pole and an N-pole are respectively arranged on an outer side and an inner side of the other magnet.

Similarly to these spin chuck side magnets, a plurality of cup side magnets are arranged radially and at equal angular intervals with the axis of rotation AX as a center. These cup side magnets are built in the lower cup 32. The lower cup 32 is a constituent component of the scattering preventing mechanism 3 to be described next and has an annular shape. That is, the lower cup 32 has an inner peripheral surface capable of facing the outer peripheral surface of the annular member 27a. An inner diameter of this inner peripheral surface is larger than an outer diameter of the annular member 27a. The lower cup 32 is arranged concentrically with the rotary shaft 22 and the annular member 27a while this inner peripheral surface is separated from the outer peripheral surface of the annular member 27a by a predetermined distance (=(the inner diameter-the outer diameter)/2) and facing the outer peripheral surface of the annular member 27a. Engaging pins and coupling magnets are provided on the upper surface of the outer peripheral edge of the lower cup 32, the upper cup 33 is coupled to the lower cup 32 by these, and this coupled body functions as the rotating cup 31. This point is described in detail later.

The lower cup 32 is supported rotatably about the axis of rotation AX on the upper surface of the the base member 17 while being kept in the above arranged state by a bearing not shown in figures. The plurality of cup side magnets are arranged radially and at equal angular intervals with the axis of rotation AX as a center on an inner peripheral edge part of this lower cup 32. Further, two cup side magnets adjacent to each other are arranged similarly to the spin chuck side magnets. That is, an N-pole and an S-pole are respectively arranged on an outer side and an inner side of one magnet, and an S-pole and an N-pole are respectively arranged on an outer side and an inner side of the other magnet.

In the power transmitter 27 thus configured, if the annular member 27a is rotated together with the rotary shaft 22 by the motor 23, the lower cup 32 rotates in the same direction as the annular member 27a while maintaining an air gap GPa (gap between the annular member 27a and the lower cup 32) by the action of magnetic forces between the spin chuck side magnets and the cup side magnets. In this way, the rotating cup 31 rotates about the axis of rotation AX. That is, the rotating cup 31 rotates in the same direction as and in synchronization with the substrate W.

The scattering preventing mechanism 3 includes the rotating cup 31 rotatable about the axis of rotation AX while surrounding the outer periphery of the substrate W held on the spin chuck 21 and a fixed cup 34 fixedly provided to surround the rotating cup 31. The rotating cup 31 is provided rotatably about the axis of rotation AX while surrounding the outer periphery of the rotating substrate W by the upper cup 33 being coupled to the lower cup 32.

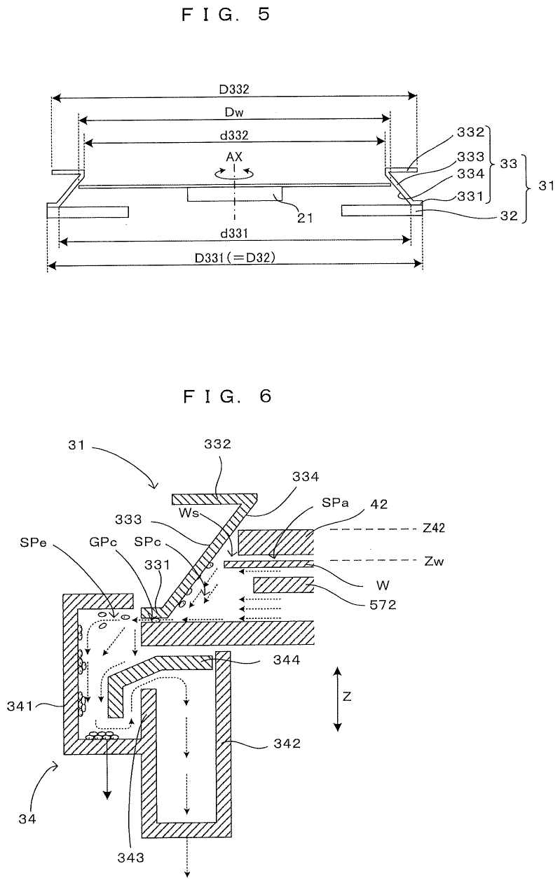

FIG. 5 is a diagram showing a dimensional relationship of the substrate held on the spin chuck and the rotating cup. FIG. 6 is a diagram partially showing a rotating cup and a fixed cup. The lower cup 32 has an annular shape. The lower cup 32 has an outer diameter larger than that of the substrate W and is arranged rotatably about the axis of rotation AX while radially protruding from the substrate W held on the spin chuck 21 in a plan view vertically from above. In this protruding region, i.e. an upper surface peripheral edge part 321 of the lower cup 32, the engaging pins standing vertically upward and the flat plate-like lower magnets 36 are alternately mounted along a circumferential direction.

On the other hand, as shown in FIGS. 2, 3, and 5, the upper cup 33 includes a lower annular part 331, an upper annular part 332 and an inclined part 333 coupling these. An outer diameter D331 of the lower annular part 331 is equal to an outer diameter D32 of the lower cup 32 and the lower annular part 331 is located vertically above the peripheral edge part 321 of the lower cup 32. Recesses open downward are provided to be fittable to tip parts of the engaging pins in regions vertically above the engaging pins on the lower surface of the lower annular part 331. Further, upper magnets are mounted in regions vertically above the lower magnets 36. Thus, the upper cup 33 is engageable with and disengageable from the lower cup 32 with the recesses and the upper magnets respectively facing the engaging pins and the lower magnets 36.

The upper cup 33 is movable up and down along the vertical direction by the elevating mechanism 7. If the upper cup 33 is moved up by the elevating mechanism 7, a conveyance space for carrying in and out the substrate W is formed between the upper cup 33 and the lower cup 32 in the vertical direction. On the other hand, if the upper cup 33 is moved down by the elevating mechanism 7, the recesses 335 are fit to cover the tip parts of the engaging pins 35 and the upper cup 33 is positioned in a horizontal direction with respect to the lower cup 32. Further, the upper magnets 37 approach the lower magnets 36, and the positioned upper and lower cups 33, 32 are bonded to each other by attraction forces generated between the both magnets. In this way, as shown in a partial enlarged view of FIG. 4 and FIG. 6, the upper and lower cups 33, 32 are integrated in the vertical direction with a gap GPc extending in the horizontal direction formed. The rotating cup 31 is rotatable about the axis of rotation AX while forming the gap GPc.

In the rotating cup 31, as shown in FIG. 5, an outer diameter D332 of the upper annular part 332 is slightly smaller than the outer diameter D331 of the lower annular part 331. Further, if diameters d331, d332 of the inner peripheral surfaces of the lower and upper annular parts 331, 332 are compared, the lower annular part 331 is larger than the upper annular part 332 and the inner peripheral surface of the upper annular part 332 is located inside the inner peripheral surface of the lower annular part 331 in a plan view vertically from above. The inner peripheral surface of the upper annular part 332 and that of the lower annular part 331 are coupled by the inclined part 333 over the entire circumference of the upper cup 33. Thus, the inner peripheral surface of the inclined part 333, i.e. a surface surrounding the substrate W, serves as an inclined surface 334. That is, as shown in FIG. 6, the inclined part 333 can collect liquid droplets scattered from the substrate W by surrounding the outer periphery of the rotating substrate W, and a space surrounded by the upper and lower cups 33, 32 functions as a collection space SPc. In the present embodiment, the height position of each part in the vertical direction Z will be called as follows. Specifically, as shown in FIG. 6, the position of the upper surface (front surface) of the substrate W held on the spin chuck 21 will be called a “height position Zw,” and the position of an upper surface of the disk part 42 of the upper surface protecting/heating mechanism 4 described later in detail will be called a “height position Z42.”

Moreover, the inclined part 333 facing the collection space SPc is inclined upwardly of the peripheral edge part of the substrate W from the lower annular part 331 forming a coupled part by being coupled to the lower cup 32. Thus, as shown in FIG. 6, liquid droplets of the processing liquid scattered from the rotating substrate W are collected at the inclined surface 334 of the inclined part 333 at the height position Zw. Then, these liquid droplets can flow to a lower end part of the upper cup 33, i.e. to the lower annular part 331 along the inclined surface 334, and can be discharged further to the outside of the rotating cup 31 via the gap GPc.

The fixed cup 34 is provided to surround the rotating cup 31 and forms a discharge space SPe. The fixed cup 34 includes a liquid receiving part 341 and an exhaust part 342 provided inside the liquid receiving part 341. The liquid receiving part 341 has a cup structure open to face an opening (left opening of FIG. 6) of the gap GPc on a side opposite to the substrate. That is, an internal space of the liquid receiving part 341 functions as the discharge space SPe and communicates with the collection space SPc via the gap GPc. Therefore, the liquid droplets collected by the rotating cup 31 are guided into the discharge space SPe via the gap GPc together with gas components. Then, the liquid droplets are collected in a bottom part of the liquid receiving part 341 and discharged from the fixed cup 34.

On the other hand, the gas components are collected into the exhaust part 342. This exhaust part 342 is partitioned from the liquid receiving part 341 via a partition wall 343. Further, a gas guiding part 344 is arranged above the partition wall 343. The gas guiding part 344 extends from a position right above the partition wall 343 into the discharge space SPe and the exhaust part 342, thereby forming a flow passage for gas components having a labyrinth structure by covering the partition wall 343 from above. Accordingly, the gas components, out of a fluid flowing into the liquid receiving part 341, are collected in the exhaust part 342 by way of the flow passage. This exhaust part 342 is connected to an exhaust part 38. Thus, a pressure in the fixed cup 34 is adjusted by the operation of the exhaust part 38 in response to a command from the control unit 10, and the gas components in the exhaust part 342 are efficiently exhausted. Further, a pressure and a flow rate in the discharge space SPe are adjusted by a precise control of the exhaust part 38. For example, the pressure in the discharge space SPe is reduced to below that in the collection space SPc. As a result, the liquid droplets in the collection space SPc can be efficiently drawn into the discharge space SPe and movements of the liquid droplets from the collection space SPc can be promoted.

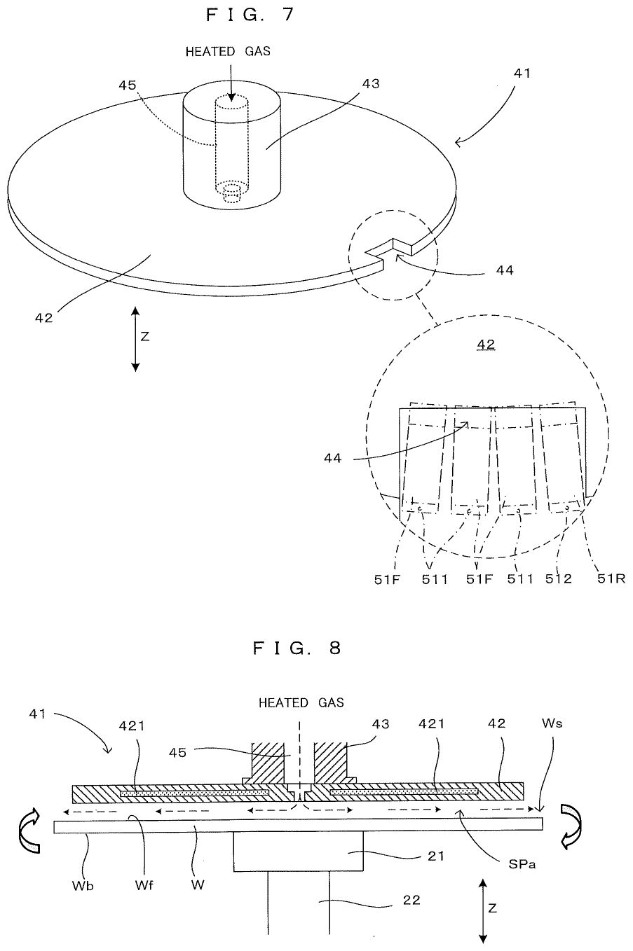

FIG. 7 is an external perspective view showing a configuration of an upper surface protecting/heating mechanism. FIG. 8 is a sectional view of the upper surface protecting/heating mechanism shown in FIG. 7. The upper surface protecting/heating mechanism 4 includes a shielding plate 41 arranged above the upper surface Wf of the substrate W held on the spin chuck 21. This shielding plate 41 includes a disk part 42 held in a horizontal posture. The disk part 42 has a built-in heater 421 drive-controlled by a heater driver 422. This disk part 42 has a diameter slightly shorter than that of the substrate W. The disk part 42 is so supported by a support member 43 that the lower surface of the disk part 42 covers a surface region excluding the peripheral edge part Ws, out of the upper surface Wf of the substrate W, from above. Note that reference sign 44 in FIG. 8 denotes a cut provided in a peripheral edge part of the disk part 42, and this cut is provided to prevent interference with processing liquid discharge nozzles included in the processing mechanism 5. The cut 44 is opened radially outward.

A lower end part of the support member 43 is mounted in a central part of the disk part 42. The cylindrical through hole is formed to vertically penetrate through the support member 43 and the disk part 42. Further, a center nozzle 45 is vertically inserted into this through hole. As shown in FIG. 2, the heated gas supplier 47 is connected to this center nozzle 45 via a pipe 46. The heated gas supplier 47 heats a nitrogen gas at a normal temperature supplied from utilities of the factory in which the substrate processing system 100 is installed and supplies the heated gas to the center nozzle 45 at a flow rate and a timing corresponding to a heated gas supply command from the control unit 10.

Herein, when the heater 471 is disposed in the internal space 12 of the chamber 11, there is a possibility that the heat radiated from the heater 471 may adversely affect the substrate processing part SP, in particular, the processing mechanism 5 and the substrate observing mechanism 9 described later. Then, in the present embodiment, the heated gas supplier 47 having the heater 471 is disposed outside the chamber 11 as shown in FIG. 4. Further, in the present embodiment, a ribbon heater 48 is mounted in a part of the pipe 46. The ribbon heater 48 generates heat in response to a heating command from the control unit 10 to heat the nitrogen gas flowing in the pipe 46.

The nitrogen gas (hereinafter, referred to as a “heated gas”) heated in this way is fed under pressure toward the center nozzle 45 and discharged from the center nozzle 45. For example, as shown in FIG. 8, by supplying the heated gas with the disk part 42 positioned at a processing position near the substrate W held on the spin chuck 21, the heated gas flows toward a peripheral edge part from a central part of a space SPa sandwiched between the upper surface Wf of the substrate W and the disk part 42 including the built-in heater. In this way, an atmosphere around the substrate W can be suppressed from reaching the upper surface Wf of the substrate W. As a result, the liquid droplets included in the atmosphere can be effectively prevented from getting in the space SPa sandwiched between the substrate W and the disk part 42. Further, the upper surface Wf is entirely heated by heating of the heater 421 and the heated gas, whereby an in-plane temperature of the substrate W can be made uniform. In this way, the warping of the substrate W can be suppressed and a liquid landing position of the processing liquid can be stabilized.

As shown in FIG. 2, an upper end part of the support member 43 is fixed to a beam member 49 extending along the first virtual horizontal line VL1. This beam member 49 is connected to the elevating mechanism 7 installed on the upper surface of the base member 17 and moved up and down by the elevating mechanism 7 in response to a command from the control unit 10. For example, in FIG. 2, the beam member 49 is positioned below, whereby the disk part 42 coupled to the beam member 49 is located at the processing position via the support member 43. On the other hand, if the elevating mechanism 7 moves up the beam member 49 in response to a move-up command from the control unit 10, the beam member 49, the support member 43 and the disk part 42 integrally move upward and the upper cup 33 is also linked, separated from the lower cup 32 and moves up. In this way, the upper cup 33 and the disk part 42 are spaced wider apart from the spin chuck 21 and the substrate W can be carried to and from the spin chuck 21.

The processing mechanism 5 includes processing liquid discharge nozzles 51F (see FIG. 4) arranged on the upper surface side of the substrate W, processing liquid discharge nozzles 51B (see FIG. 2) arranged on the lower surface side of the substrate W and processing liquid suppliers 52 for supplying the processing liquid to the processing liquid discharge nozzles 51F, 51B. The lower processing liquid discharge nozzles 51F on the upper surface side and the processing liquid discharge nozzles 51B on the lower surface side are respectively referred to as “upper surface processing nozzles 51F” and “lower surface processing nozzles 51B” to be distinguished. Further, two processing liquid suppliers 52 shown in FIG. 2 are identical.

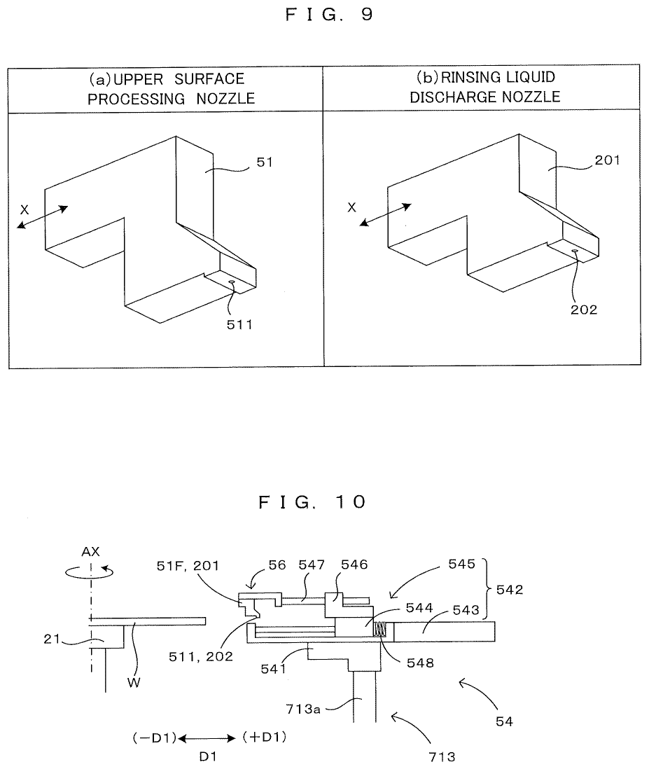

FIG. 9 is a perspective diagram showing the processing liquid discharge nozzle on the upper surface side provided at the processing mechanism and a cup rinsing liquid discharge nozzle on the upper surface side provided at the cup rinsing mechanism, which is a diagram showing each nozzle viewed in a direction from obliquely below. In the present embodiment, three upper surface processing nozzles 51F are provided as processing liquid discharge nozzles on the upper surface side for discharging the processing liquid from above the substrate W held on the spin chuck 21 toward the peripheral edge part Ws of the upper surface Wf of the substrate W, and the processing liquid supplier 52 is connected to these nozzles. The processing liquid supplier 52 is configured to allow supply of SC1, DHF, and functional water (CO2 water or the like) as the processing liquids, and the SC1, DHF, and functional water can be respectively independently discharged from the three upper surface processing nozzles 51F.

As shown in the column (a) of FIG. 9, each of the upper surface processing nozzles 51F is provided with a discharge port 511 for discharging the processing liquid formed in a lower surface of a tip thereof. As shown in an enlarged view of FIG. 4, in postures of making the respective discharge ports face the peripheral edge part of the upper surface Wf of the substrate W, lower parts of a plurality of (in the present embodiment, three) upper surface processing nozzles 51F are arranged in the cut 44 of the disk part 42 together with a rinsing liquid discharge nozzle 201 shown in a partially enlarged plan view of FIG. 7, and upper parts of the upper surface processing nozzles 51F are mounted on a nozzle holder 53 integrally with the rinsing liquid discharge nozzle 201 and movably in a radial direction DI (in a direction inclined with respect to the first virtual horizontal line VL1 with a nozzle discharge elevation angle of about 45° and a turning angle of about 65°). The nozzle holder 53 is connected to a nozzle mover 54.

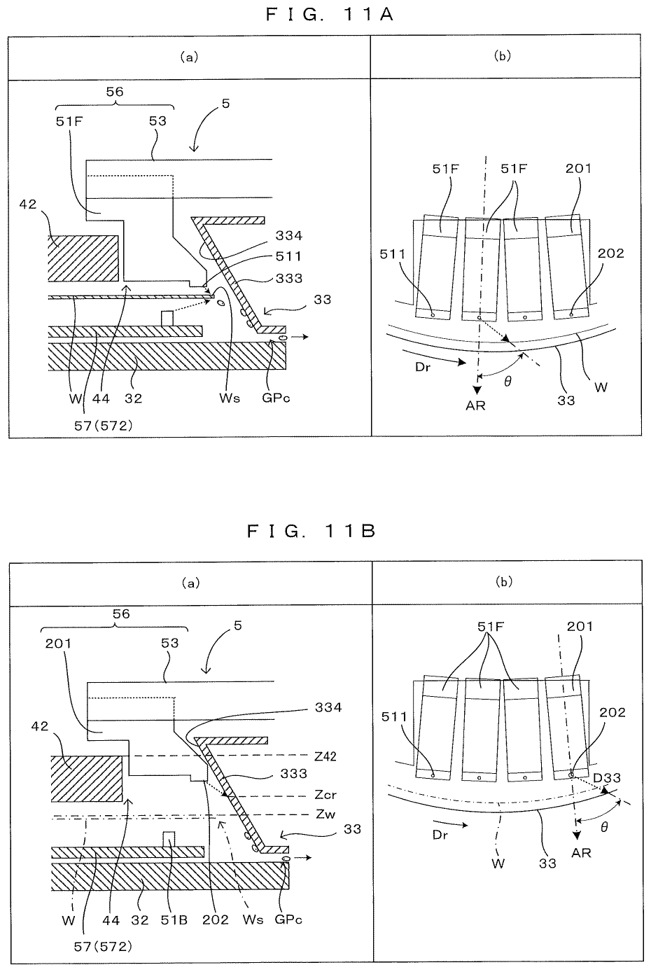

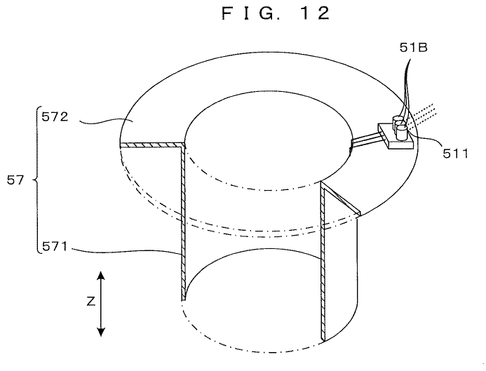

FIG. 10 is a diagram schematically showing a configuration of the nozzle mover. FIG. 11A is a schematic diagram showing a nozzle position for implementation of the bevel processing. FIG. 11B is a schematic diagram showing a nozzle position for implementation of cup rinsing processing. In each of FIGS. 11A and 11B, the column (a) is a side view of the nozzle for discharging the processing liquid or the cup rinsing liquid, and the column (b) is a plan view of the nozzle from above. A sign AR shows a radial direction extending from the axis of rotation AX toward the nozzle from which the processing liquid or the cup rinsing liquid is discharged.

As shown in FIG. 10, the nozzle mover 54 is attached to an upper end part of a lifter 713a of an elevator 713 described later while holding the nozzle head 56 (=the upper surface processing nozzle 51F+the nozzle holder 53). For this reason, in response to an up-and-down command from the control unit 10, the lifter 713a expands and contracts in the vertical direction and accordingly the nozzle mover 54 and the nozzle head 56 move in the vertical direction Z.

In the nozzle mover 54, a base member 541 is fixed to the upper end part of the lifter 713a. To this base member 541, attached is a linear actuator 542. The linear actuator 542 has a motor (hereinafter, referred to as a “nozzle drive motor”) 543 serving as a drive source of nozzle movement in the radial direction X and a motion conversion mechanism 545 for converting a rotational motion of a rotating body such as a ball screw or the like coupled to an axis of rotation of the nozzle drive motor 543 into a linear motion to thereby cause a slider 544 to reciprocally move in the radial direction D1. Further, in the motion conversion mechanism 545, in order to stabilize the movement of the slider 544 in the radial direction D1, a guide such as an LM guide (registered trademark) or the like is used.

To the slider 544 driven reciprocally in the radial direction X, a head support member 547 is coupled with a coupling member 546 interposed therebetween. This head support member 547 has a bar shape extending in the radial direction X. An end part of the head support member 547 in the (+D1) direction is fixed to the slider 544. On the other hand, an end part of the head support member 547 in the (−D1) direction is horizontally extended toward the spin chuck 21, and the nozzle head 56 is attached to a tip part thereof. For this reason, when the nozzle drive motor 543 is rotated in response to a nozzle moving command from the control unit 10, the slider 544, the head support member 547, and the nozzle head 56 are integrally moved in the (+D1) direction or the (−D1) direction in accordance with a rotation direction thereof by a distance corresponding to the amount of rotation. As a result, the upper surface processing nozzle 51F attached to the nozzle head 56 is positioned in the radial direction D1. As shown in FIG. 10, for example, when the upper surface processing nozzle 51F is positioned at a home position which is set in advance, a spring member 548 provided in the motion conversion mechanism 545 is compressed by the slider 544, to thereby give an urging force to the slider 544 in the (−X) direction. It is thereby possible to control backlash included in the motion conversion mechanism 545. Specifically, since the motion conversion mechanism 545 has mechanical components such as a guide or the like, it is practically difficult to make the backlash along the radial direction DI zero, and the positioning accuracy of the upper surface processing nozzle 51F in the radial direction D1 is reduced if not sufficient consideration is made thereon. Then, in the present embodiment, by providing the spring member 548, when the upper surface processing nozzle 51F is immobilized at the home position, the backlash is always one-sided toward the (−D1) direction. This produces the following effects.

In response to a nozzle moving command from the control unit 10, the nozzle mover 54 drives the three upper surface processing nozzles 51F and the rinsing liquid discharge nozzle 201 collectively in the radial direction D1. This nozzle moving command contains information on a nozzle moving distance. On the basis of the information, the upper surface processing nozzles 51F and the rinsing liquid discharge nozzle 201 ae moved in the radial direction D1 by the specified nozzle moving distance. Here, if the foregoing information corresponds to a bevel processing position, the upper surface processing nozzle 51F is accurately positioned at the bevel processing position (corresponding to one example of a “substrate processing position” of the present invention), as shown in FIG. 11A. If the foregoing information corresponds to a cup rinsing processing position, the rinsing liquid discharge nozzle 201 is accurately positioned at the cup rinsing position, as shown in FIG. 11B.

The discharge port 511 of the upper surface processing nozzle 51F positioned at the bevel processing position faces the peripheral edge part of the upper surface Wf of the substrate W. When the processing liquid supplier 52 supplies a processing liquid in response to a supply command from the control unit 10 to the upper surface processing nozzle 51F for this processing liquid which is one of the three types of processing liquids and corresponding to the supply command, the processing liquid is supplied from the upper surface processing nozzle 51F to a preset position from an end surface of the substrate W. During implementation of the bevel processing, supply of the cup rinsing liquid to the rinsing liquid discharge nozzle 201 is stopped.

Meanwhile, a discharge port 202 of the rinsing liquid discharge nozzle 201 positioned at the cup rinsing position faces the inclined part 333 of the upper cup 33. The discharge port 202 is provided at the rinsing liquid discharge nozzle 201 in such a manner as to be opened to a diameter larger than the diameter of the discharge port 511 of the upper surface processing nozzle 51F. When a cup rinsing liquid supplier 203 (FIG. 2) supplies the cup rinsing liquid such as DIW (deionized water) at a normal temperature to the rinsing liquid discharge nozzle 201 in response to a supply command from the control unit 10, the cup rinsing liquid is supplied from the rinsing liquid discharge nozzle 201 to the inclined part 333, as shown in FIG. 11B. As shown in FIG. 11B, in the present embodiment, a discharge direction D33 of the cup rinsing liquid is inclined by an angle θ toward a rotation direction Dr of the upper cup 33 with respect to the radial direction AR extending from the axis of rotation AX toward the rinsing liquid discharge nozzle 201 within a horizontal plane (XY plane). This makes it possible to effectively prevent bouncing of the cup rinsing liquid occurring during collision of the cup rinsing liquid with the inclined part 333 from returning to the rinsing liquid discharge nozzle 201. As shown in FIG. 11A, in the present embodiment, discharge of the processing liquid is also inclined by the angle θ toward the rotation direction Dr of the upper cup 33 with respect to the radial direction AR. The angle θ is set freely and can be set as θ=zero, for example. During implementation of the cup rinsing processing, supply of the processing liquid to the upper surface processing nozzle 51F is stopped.

Further, to part of the constituent components of the nozzle mover 54, a lower sealing cup member 61 of the atmosphere separating mechanism 6 is detachably fixed. Specifically, when the bevel processing is performed, the upper surface processing nozzle 51F and the nozzle holder 53 are integrated with the lower sealing cup member 61 with the nozzle mover 54 interposed therebetween and moved up and down in the vertical direction Z together with the lower sealing cup member 61 by the elevating mechanism 7.

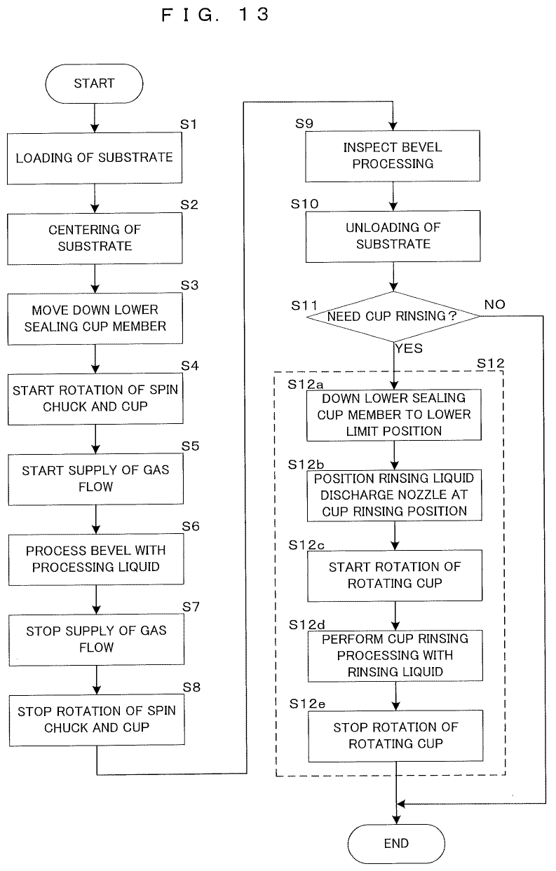

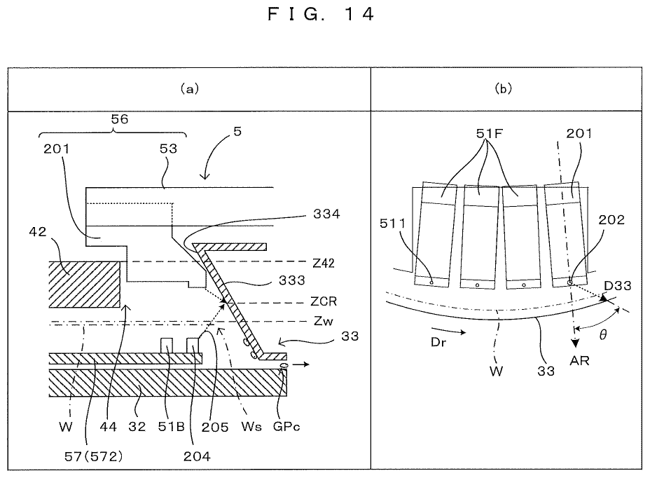

FIG. 12 is a perspective diagram showing the lower surface side processing liquid discharge nozzle and the nozzle support that supports the same nozzle, both of which are equipped in the processing mechanism. In the present embodiment, the lower surface processing nozzles 51B and a nozzle support 57 are provided below the substrate W held on the spin chuck 21 to discharge the processing liquid toward the peripheral edge part of the lower surface Wb of the substrate W. As shown in FIG. 13, the nozzle support 57 includes a thin hollow cylindrical part 571 extending in the vertical direction and a flange part 572 having an annular shape and bent to expand radially outward in an upper end part of the hollow cylindrical part 571. The hollow cylindrical part 571 is shaped to be loosely insertable into the air gap GPa formed between the annular member 27a and the lower cup 32. As shown in FIG. 2, the nozzle support 57 is so fixedly arranged that the hollow cylindrical part 571 is loosely inserted in the air gap GPa and the flange part 572 is located between the substrate W supported on the spin chuck 21 and the lower cup 32. Three lower surface processing nozzles 51B are mounted on a peripheral edge part of the upper surface of the flange part 572. Each lower surface processing nozzle 51B includes a discharge port (not shown) open toward the peripheral edge part of the lower surface Wb of the substrate W and can discharge the processing liquid supplied from the processing liquid supplier 52 via a pipe 58.

The bevel processing for the peripheral edge part of the substrate W is performed by the processing liquids discharged from these upper surface processing nozzle 51F and lower surface processing nozzles 51B. Further, on the lower surface side of the substrate W, the flange part 572 is extended to the vicinity of the peripheral edge part Ws. Thus, the nitrogen gas supplied to the lower surface side via the pipe 28 flows into the collection space SPc along the flange part 572. As a result, a backflow of the liquid droplets from the collection space SPc to the substrate W is effectively suppressed.

The atmosphere separating mechanism 6 includes the lower sealing cup member 61 and an upper sealing cup member 62. Both of the upper and lower sealing cup members 61, 62 have a tube shape open in the vertical direction. Inner diameters of those are larger than an outer diameter of the rotating cup 31, and the atmosphere separating mechanism 6 is arranged to completely surround the spin chuck 21, the substrate W held on the spin chuck 21, the rotating cup 31 and the upper surface protecting/heating mechanism 4 from above. More particularly, as shown in FIG. 2, the upper sealing cup member 62 is fixedly arranged at a position right below the punching plate 14 such that the upper opening thereof covers the opening 11f1 of the ceiling wall 11f from below. Thus, a downflow of clean air introduced into the chamber 11 is separated into a flow passing through the inside of the upper sealing cup member 62 and a flow passing outside the upper sealing cup member 62.

Further, a lower end part of the upper sealing cup member 62 includes a flange part 621 bent inwardly and having an annular shape. An O-ring 63 is mounted on the upper surface of this flange part 611. The lower sealing cup member 61 is arranged movably in the vertical direction inside the upper sealing cup member 62.

An upper end part of the lower sealing cup member 61 includes a flange part 611 bent to expand outward and having an annular shape. The flange part 611 overlaps the flange part 621 in a plan view vertically from above. Thus, if the lower sealing cup member 61 moves down, as shown in the partial enlarged view of FIG. 4, the flange part 611 of the lower sealing cup member 61 is locked by the flange part 621 of the upper sealing cup member 62 via the O-ring 63 as shown in FIGS. 3 and 14. In this way, the lower sealing cup member 61 is positioned at a lower limit position. At this lower limit position, the upper and lower sealing cup members 62, 61 are connected in the vertical direction, and a downflow introducing into the upper sealing cup member 62 is guided toward the substrate W held on the spin chuck 21.

A lower end part of the lower sealing cup member 61 includes a flange part 612 bent outwardly and having an annular shape. This flange part 612 overlaps an upper end part of the fixed cup 34 (upper end part of the liquid receiving part 341) in a plan view vertically from above. Thus, at the lower limit position, the flange part 612 of the lower sealing cup member 61 is locked by the fixed cup 34 via an O-ring 64 as shown in the enlarged view of FIG. 4. In this way, the lower sealing cup member 61 and the fixed cup 34 are connected in the vertical direction, and a sealed space 12a is formed by the upper sealing cup member 62, the lower sealing cup member 61 and the fixed cup 34. The bevel processing on the substrate W can be performed in this sealed space SPs. That is, by positioning the lower sealing cup member 61 at the lower limit position, the sealed space 12a is separated from an outside space 12b of the sealed space 12a (atmosphere separation). Therefore, the bevel processing can be stably performed without being influenced by an outside atmosphere. Further, the processing liquids are used to perform the bevel processing. The processing liquids can be reliably prevented from leaking from the sealed space 12a to the outside space 12b. Thus, a degree of freedom in selecting/designing components to be arranged in the outside space 12b is enhanced.

The lower sealing cup member 61 is also configured to be movable vertically upward. The nozzle head 56 (=upper surface processing nozzle 51F+rinsing liquid discharge nozzle 201+nozzle holder 53) is fixed to an intermediate part of the lower sealing cup member 61 in the vertical direction via the the head support member 547 of the nozzle mover 54 as described above. Besides this, as shown in FIGS. 2 and 4, the upper surface protecting/heating mechanism 4 is fixed to an intermediate part of the lower sealing cup member 61 via the beam member 49. That is, as shown in FIG. 4, the lower sealing cup member 61 is connected to one end part of the beam member 49, the other end part of the beam member 49 and the head support member 547 of the nozzle mover 54 at three positions mutually different in the circumferential direction. By moving up and down the one end part of the beam member 49, the other end part of the beam member 49 and the support member 547 by the elevating mechanism 7, the lower sealing cup member 61 is also moved up and down accordingly.

As shown in FIGS. 2 and 4, a plurality of (four) projections 613 are provided to project inward as engaging parts engageable with the upper cup 33 on the inner peripheral surface of the lower sealing cup member 61. Each projection 613 extends to a space below the upper annular part 332 of the upper cup 33. Further, each projection 613 is so mounted to be separated downward from the upper annular part 332 of the upper cup 33 with the lower sealing cup member 61 positioned at the lower limit position. By an upward movement of the lower sealing cup member 61, each projection 613 is engageable with the upper annular part 332 from below. The lower sealing cup member 61 moves further upward also after this engagement, whereby the upper cup 33 can be separated from the lower cup 32.

In the present embodiment, after the lower sealing cup member 61 starts to be moved up together with the upper surface protecting/heating mechanism 4 and the nozzle head 56 by the elevating mechanism 7, the upper cup 33 also moves up. In this way, the upper cup 33, the upper surface protecting/heating mechanism 4 and the nozzle head 56 are separated upward from the spin chuck 21. By a movement of the lower sealing cup member 61 to a retracted position, the conveyance space for allowing the hand (RH in FIG. 16A) of the substrate conveyor robot 111 to access the spin chuck 21 is formed. The substrate W can be loaded onto the spin chuck 21 and unloaded from the spin chuck 21 via this conveyance space. As just described, in the present embodiment, the substrate W can access the spin chuck 21 by a minimum upward movement of the lower sealing cup member 61 by the elevating mechanism 7.

The elevating mechanism 7 includes two elevation drivers 71, 72. In the elevation driver 71, a first elevation motor (not shown) is attached to a first elevation mounting portion 173 (FIG. 3) of the base member 17. The first elevation motor generates a rotational force by operating in response to a drive command from the control unit 10. Two elevators 712, 713 are coupled to this first elevation motor 711. The elevators 712, 713 simultaneously receive the rotational force from the first elevation motor 711. Then, the elevator 712 moves up and down a support member 491 supporting the one end part of the beam member 49 along the vertical direction Z according to a rotation amount of the first elevation motor 711. Further, the elevator 713 moves up and down the support member 54 supporting the nozzle head 56 along the vertical direction Z according to the rotation amount of the first elevation motor 711.

In the elevation driver 72, a second elevation motor (not shown) is attached to a second elevation mounting portion 174 (FIG. 3) of the base member 17. An elevator 722 is coupled with the second elevation motor. The second elevation motor generates a rotational force by operating in response to a drive command from the control unit 10 and gives the generated rotational force to the elevator 722. The elevator 722 moves up and down a support member 492 supporting the other end part of the beam member 49 along the vertical direction according to the amount of rotation of the second elevation motor.

The elevation drivers 71, 72 synchronously and vertically move the support members 491, 492 and 54 respectively fixed to the side surface of the lower sealing cup member 61 at three positions mutually different in the circumferential direction. Therefore, the upper surface protecting/heating mechanism 4, the nozzle head 56 and the lower sealing cup member 61 can be stably moved up and down. Further, the upper cup 33 can be also stably moved up and down as the lower sealing cup member 61 is moved up and down.

The centering mechanism 8 performs centering processing while the suction by the pump 26 is stopped (i.e. while the substrate W is horizontally movable on the upper surface of the spin chuck 21). By this centering processing, the eccentricity of the substrate W with respect to the axis of rotation AX is eliminated and a center of the substrate W coincides with the axis of rotation AX. As shown in FIG. 4, the centering mechanism 8 has a single contact part 81 disposed on a side of the convey ance opening 11b1 with respect to the axis of rotation AX in a contact movement direction D2 inclined at about 40° with respect to the first virtual horizontal line VL1, a multi-contact part 82 disposed on a side of the maintenance opening 11d1, and a centering driver 83 for moving the single contact part 81 and the multi-contact part 82 in the contact movement direction D2.

The single contact part 81 has a shape extending in parallel to the contact movement direction D2 and is finished to be contactable with the end surface of the substrate W on the spin chuck 21 at a tip part on the side of the spin chuck 21. On the other hand, the multi-contact part 82 has a substantial Y shape in a plan view vertically from above and is finished to be contactable with the end surface of the substrate W on the spin chuck 21 at each tip part of a bifurcated portion on the side of the spin chuck 21. The single contact part 81 and the multi-contact part 82 are movable in the contact movement direction D2.

The centering driver 83 has a single mover 831 for moving the single contact part 81 in the contact movement direction D2 and a multi-mover 832 for moving the multi-contact part 82 in the contact movement direction D2. The single mover 831 is mounted on a single moving attachment portion 175 (FIG. 3) of the base member 17 and the multi-mover 832 is mounted on a multi-moving attachment portion 176 (FIG. 3) of the base member 17. While the centering processing of the substrate W is not performed, as shown in FIG. 4, the centering driver 83 positions the single contact part 81 and the multi-contact part 82 away from the spin chuck 21. For this reason, the single contact part 81 and the multi-contact part 82 are away from the conveyance path TP, and it is thereby possible to effectively prevent interference of the single contact part 81 and the multi-contact part 82 with the substrate W loaded into or unloaded from the chamber 11.

On the other hand, when the centering processing of the substrate W is performed, in response to a centering command from the control unit 10, the single mover 831 move the single contact part 81 toward the axis of rotation AX and the multi-mover 832 moves the multi-contact part 82 toward the axis of rotation AX. The center of the substrate W thereby coincides with the axis of rotation AX

The substrate observing mechanism 9 has a light source part 91, an image pickup part 92, an observation head 93, and an observation head driver 94. The light source part 91 and the image pickup part 92 are arranged in parallel at an optical component attachment position 177 (FIG. 3) of the base member 17. In response to a lighting command from the control unit 10, the light source part 91 emits illumination light toward an observation position. This observation position is a position (not shown) corresponding to the peripheral edge part Ws of the substrate W, which corresponds to a position at which the observation head 93 is positioned in FIG. 12.

The observation head 93 is reciprocally movable between the observation position and a separation position away from the observation position outside in a radial direction of the substrate W. The observation head driver 94 is connected to the observation head 93. The observation head driver 94 is attached to the base member 17 at a head driving position 178 (FIG. 3) of the base member 17. In response to a head moving command from the control unit 10, the observation head driver 94 causes the observation head 93 to reciprocally move in a head movement direction D3 inclined at about 10° with respect to the first virtual horizontal line VL1. More specifically, while observation processing of the substrate W is not performed, the observation head driver 94 causes the observation head 93 to move to the retracted position, to be positioned. For this reason, the observation head 93 is away from the conveyance path TP, and it is thereby possible to effectively prevent interference of the observation head 93 with the substrate W loaded into or unloaded from the chamber 11. On the other hand, when the observation processing of the substrate W is performed, in response to a substrate observing command from the control unit 10, the observation head driver 94 causes the observation head 93 to move to the observation position.

When the observation head 93 having such a configuration is positioned at the observation position and the light source part 91 lights up in response to a lighting command from the control unit 10 in the positioning state, illumination light is applied to a lighting area of the observation head 93. By doing so, the peripheral edge part Ws of the substrate W and an adjacent area thereof are illuminated with diffused illumination light from the observation head 93. Furthermore, reflected light reflected on the peripheral edge part Ws and the adjacent area thereof is guided to the image pickup part 92 via the observation head 93.

The image pickup part 92 has an observation lens system consisting of object-side telecentric lenses and a CMOS camera. Therefore, among the reflected light guided from the observation head 93, only rays of light in parallel to the optical axis of the observation lens system enter a sensor surface of the CMOS camera and an image of the peripheral edge part Ws of the substrate W and the adjacent area thereof is formed on the sensor surface. Thus, the image pickup part 92 images the peripheral edge part Ws of the substrate W and the adjacent area thereof and acquires an upper-surface image, a side-surface image, and a lower-surface image of the substrate W. Then, the image pickup part 92 transmits image data representing these images to the control unit 10.

The control unit 10 includes an arithmetic processor 10A, a storage 10B, a reader 10C, an image processor 10D, a drive controller 10E, a communicator 10F and an exhaust controller 10G. The storage 10B is constituted by a hard disk drive or the like, and stores a program for performing the bevel processing by the substrate processing apparatus 1. This program is stored, for example, in a computer-readable recording medium RM (e.g. an optical disk, a magnetic disk, a magneto-optical disk, or the like), read from the recording medium RM by the reader 10C and saved in the storage 10B. Further, the program may be provided, for example, via an electrical communication line without being limited to provision via the recording medium RM. The image processor 10D applies various processings to an image captured by the substrate observing mechanism 9. The drive controller 10E controls each driver of the substrate processing apparatus 1. The communicator 10F conducts communication with a controller for integrally controlling each component of the substrate processing system 100 and the like. The exhaust controller 10G controls the exhaust part 38.

Further, a display unit 10H (e.g. a display and the like) for displaying various pieces of information and an input unit (e.g. a keyboard, a mouse and the like) for receiving an input from an operator are connected to the control unit 10.

The arithmetic processor 10A is constituted by a computer including a CPU (=Central Processing Unit), a RAM (=Random Access Memory) and the like, and performs the bevel processing by controlling each component of the substrate processing apparatus 1 in accordance with the program stored in the storage 10B as described below. The bevel processing by the substrate processing apparatus 1 is described below with reference to FIG. 14.

FIG. 13 is a flowchart showing bevel processing performed, as an example of a substrate processing operation, by the substrate processing apparatus shown in FIG. 2. In applying the bevel processing to the substrate W by the substrate processing apparatus 1, the arithmetic processor 10A causes the elevation drivers 71, 72 to integrally move up the lower sealing cup member 61, the nozzle head 56, the beam member 49, the support member 43 and the disk part 42. While the lower sealing cup member 61 is moving up, the projections 613 are engaged with the upper annular part 332 of the upper cup 33 and, thereafter, the upper cup 33 is moved up together with the lower sealing cup member 61, the nozzle head 56, the beam member 49, the support member 43 and the disk part 42 and positioned at the retracted position. In this way, the conveyance space sufficient to allow the entrance of the hand (not shown) of the substrate conveyor robot 111 is formed above the spin chuck 21. Further, the arithmetic processor 10A uses the centering driver 83 to move the single mover 831 and the multi-contact part 82 to the retracted position away from the spin chuck 21 and also uses the observation head driver 94 to move the observation head 93 to a waiting position away from the spin chuck 21. Among the constituent elements arranged around the spin chuck 21, as shown in FIG. 4, the nozzle head 56, the light source part 91, the image pickup part 92, the motor 23, and the multi-contact part 82 are thereby positioned on the side of the maintenance opening (the lower side in this figure) relative to the first virtual horizontal line VL1. Further, though the single mover 831 and the observation head 93 are positioned on the side of the conveyance opening 11b1 relative to the first virtual horizontal line VL1, these constituent elements are out of a moving area of the substrate W along the conveyance path TP. In the present embodiment, since such a layout structure is adopted, in loading of the substrate W into or out from the chamber 11, it is possible to effectively prevent interference of the constituent elements arranged around the spin chuck 21 with the substrate W.

After confirming the completion of the formation of the conveyance space and the prevention of interference with the substrate W, the arithmetic processor 10A gives a loading request of the substrate W to the substrate conveyor robot 111 via the communicator 10F and it is waited until an unprocessed substrate W is carried into the substrate processing apparatus 1 along the conveyance path TP shown in FIG. 4 and placed on the upper surface of the spin chuck 21. Then, the substrate W is placed on the spin chuck 21 (Step S1). Note that, at this point of time, the pump 26 is stopped and the substrate W is horizontally movable on the upper surface of the spin chuck 21.

If the loading of the substrate W is completed, the substrate conveyor robot 111 is retracted along the conveyance path TP from the substrate processing apparatus 1. Following that, the arithmetic processor 10A controls the centering driver 83 such that the single contact part 81 and the multi-contact part 82 approach the substrate W. In this way, the eccentricity of the substrate W with respect to the spin chuck 21 is eliminated and the center of the substrate W coincides with that of the spin chuck 21 (Step S2). If the centering processing is completed in this way, the arithmetic processor 10A controls the centering driver 82 to separate the three contact members 81 from the substrate W and operates the pump 26 to apply a negative pressure to the spin chuck 21. In this way, the spin chuck 21 sucks and holds the substrate W from below.

Subsequently, the arithmetic processor 10A gives a move-down command to the elevation drivers 71, 72. In response to this, the elevation drivers 71, 72 integrally move down the lower sealing cup member 61, the nozzle head 56, the beam member 49, the support member 43 and the disk part 42. During these downward movements, the upper cup 33 supported from below by the projections 613 of the lower sealing cup member 61 is coupled to the lower cup 32. This forms the rotating cup 31 (=a coupled body of the upper cup 33 and the lower cup 32).

After the rotating cup 31 is formed, the lower sealing cup member 61, the nozzle head 56, the beam member 49, the support member 43 and the disk part 42 are further integrally moved down, and the flange parts 611, 612 of the lower sealing cup member 61 are respectively locked by the flange part 621 of the upper sealing cup member 62 and the fixed cup 34. In this way, the lower sealing cup member 61 is positioned at the lower limit position (position in FIG. 2) (Step S3). After the above locking, the flange part 621 of the upper sealing cup member 62 and the flange part 611 of the lower sealing cup member 61 are held in close contact via the O-ring 63, and the flange part 612 of the lower sealing cup member 61 and the fixed cup 34 are held in close contact via the O-ring 63. As a result, as shown in FIG. 2, the lower sealing cup member 61 and the fixed cup 34 are connected in the vertical direction, and the sealed space SPs is formed by the upper sealing cup member 62, the lower sealing cup member 61 and the fixed cup 34, and the sealed space SPs is separated from the outside atmosphere (outside space SPo) (atmosphere separation).

In this atmosphere separated state, the lower surface of the disk part 42 covers the surface region excluding the peripheral edge part Ws, out of the upper surface Wf of the substrate W, from above. Further, the upper surface processing nozzles 51F are positioned in such a posture that the discharge ports 511 are facing the peripheral edge part of the upper surface Wf of the substrate W in the cut 44 of the disk part 42. If preparation for the supply of the processing liquids to the substrate W is completed in this way, the arithmetic processor 10A gives a rotation command to the rotation driver 23 to start the rotation of the spin chuck 21 holding the substrate W and the rotating cup 31 (Step S4). Rotating speeds of the substrate W and the rotating cup 31 are set, for example, at 1800 rpm. Further, the arithmetic processor 10A controls the drive of the heater driver 422 to heat the heater 421 to a desired temperature, e.g. 185 °C.

Next, the arithmetic processor 10A gives the heated gas supply command to the heated gas supplier 47. The nitrogen gas heated by the heater 471, i.e., the heated gas is thereby fed under pressure from the heated gas supplier 47 toward the center nozzle 45 (Step S5). This heated gas is heated by the ribbon heater 48 during passing through the pipe 46. This heated gas is thereby discharged from the center nozzle 45 toward the space SPa (FIG. 8) sandwiched between the substrate W and the disk part 42 while a decrease in the temperature is prevented during the gas supply through the pipe 46. The entire upper surface Wf of the substrate W is thereby heated. Further, the substrate W is also heated by the heater 421. For this reason, the temperature of the peripheral edge part Ws of the substrate W rises with the passage of time and reaches a temperature suitable for the bevel processing, e.g. 90 °C. Further, the temperature of the substrate W other than the peripheral edge part Ws also rises to a substantially equal temperature. In other words, in the present embodiment, the in-plane temperature of the upper surface Wf of the substrate W is substantially uniform. Therefore, the warping of the substrate W can be effectively suppressed.

Following this, the arithmetic processor 10A supplies the processing liquids to the upper surface processing nozzles 51F and the lower surface processing nozzles 51B by controlling the processing liquid suppliers 52. That is, flows of the processing liquids are discharged from the upper surface processing nozzles 51F to contact the peripheral edge part of the upper surface of the substrate W, and flows of the processing liquids are discharged from the lower surface processing nozzles 51B to contact the peripheral edge part of the lower surface of the substrate W. In this way, the bevel processing is performed on the peripheral edge part Ws of the substrate W (Step S6). Upon detecting the passage of a processing time required for the bevel processing of the substrate W, the arithmetic processor 10A gives a supply stop command to the processing liquid suppliers 52 to stop the discharge of the processing liquids.

Following that, the arithmetic processor 10A gives a supply stop command to the nitrogen gas supplier 47 to stop the supply of the nitrogen gas from the nitrogen gas supplier 47 to the center nozzle 45 (Step S7). Further, the arithmetic processor 10A gives a rotation stop command to the rotation driver 23 to stop the rotation of the spin chuck 21 and the rotating cup 31 (Step S8).

In next Step S9, the arithmetic processor 10A observes the peripheral edge part Ws of the substrate W to inspect a result of the bevel processing. More specifically, the arithmetic processor 10A positions the upper cup 33 at the retracted position to form the conveyance space in the same manner as that during the loading of the substrate W. Then, the arithmetic processor 10A controls the observation head driver 94 to bring the observation head 93 closer to the substrate W. Then, the arithmetic processor 10A lights the light source part 91 to illuminate the peripheral edge part Ws of the substrate W through the observation head 93. Further, the image pickup part 92 receives the reflected light which is reflected by the peripheral edge part Ws and the adjacent area, to thereby image the peripheral edge part Ws and the adjacent area. Specifically, a peripheral-edge-part image of the peripheral edge part Ws along the rotation direction of the substrate W is acquired out of a plurality of images of the peripheral edge part Ws acquired by the image pickup part 92 while the substrate W is rotated about the axis of rotation AX. Then, the arithmetic processor 10A controls the observation head driver 94 to retract the observation head 93 from the substrate W. In parallel with this, the arithmetic processor 10A inspects whether or not the bevel processing has been satisfactorily performed, on the basis of the picked-up image of the peripheral edge part Ws and the adjacent area, i.e., the peripheral-edge-part image. Further, in the present embodiment, as an example of the inspection, a processing width is inspected from the peripheral-edge-part image, which is processed by using the processing liquids, from the end surface of the substrate W toward the central part of the substrate W (inspection after processing).

After the inspection, the arithmetic processor 10A gives an unloading request for the substrate W to the substrate conveyor robot 111 via the communicator 10F, and the processed substrate W is unloaded from the substrate processing apparatus 1 (Step S10). Subsequently to this, the arithmetic processor 10A judges whether timing for performing the cup rinsing processing on the rotating cup 31 has come (Step S11). The timing mentioned herein is judged to have come if a frequency of implementations of the bevel processing or a cumulative period of time of the implementations has reached a predetermined value after change of the rotating cup 31 or after implementation of previous maintenance, for example. This timing also includes timing when an operator gives a request for cup rinsing.

If the arithmetic processor 10A judges that the cup rinsing processing is unnecessary (“NO” in Step S11), a series of the processes is finished without performing the cup rinsing processing. On the other hand, if the arithmetic processor 10A judges that the cup rinsing processing is necessary (“YES” in Step S11), the cup rinsing processing is performed (Step S12).

In the cup rinsing processing (Step S12), the arithmetic processor 10A controls each part of the apparatus as follows (Steps S12a to S12e). Specifically, the arithmetic processor 10A gives a move-down command to the elevation drivers 71 and 72. In response to this, the elevation drivers 71 and 72 move down the lower sealing cup member 61, the nozzle head 56, the beam member 49, the support member 43, and the disk part 42 integrally. During these downward movements, the upper cup 33 supported from below by the projections 613 of the lower sealing cup member 61 is coupled to the lower cup 32. By doing so, the rotating cup 31 (=a coupled body of the upper cup 33 and the lower cup 32) is formed while the substrate W is still absent on the spin chuck 21.

After the rotating cup 31 is formed, the lower sealing cup member 61, the nozzle head 56, the beam member 49, the support member 43, and the disk part 42 are further integrally moved down, and the flange parts 611 and 612 of the lower sealing cup member 61 are respectively locked by the flange part 621 of the upper sealing cup member 62 and the fixed cup 34. In this way, the lower sealing cup member 61 is positioned at the lower limit position (position in FIG. 2) (Step S12a).

As shown in FIG. 11B, in this atmosphere separated state, the lower surface of the disk part 42 covers the surface region excluding the peripheral edge part Ws, out of the upper surface Wf of the substrate W, from above. The arithmetic processor 10A gives a drive command to the nozzle drive motor 543. The slider 544, the head support member 547, and the nozzle head 56 are integrally moved by a distance corresponding to a rotation amount provided in the drive command. As a result, the rinsing liquid discharge nozzle 201 is positioned at the cup rinsing position (the position illustrated in FIG. 11B) suitable for the cup rinsing processing while the rinsing liquid discharge nozzle 201 is in the cut 44 of the disk part 42 and in a posture of making the discharge port 202 face the inclined part 333 of the upper cup 33 (Step S12b).

When preparation for supplying the cup rinsing liquid to the rotating cup 31 is completed in this way, the arithmetic processor 10A gives a rotation command to the motor 23, thereby starting rotations of the spin chuck 21 holding the substrate W and the rotating cup 31 (Step S12c). During the cup rinsing processing, rotating speeds of the substrate W and the rotating cup 31 are set lower than the rotating speeds during the bevel processing and are set from 100 to 500 rpm, for example.

Next, the arithmetic processor 10A controls the cup rinsing liquid supplier 203 to supply the cup rinsing liquid to the rinsing liquid discharge nozzle 201. Specifically, the cup rinsing liquid is discharged from the rinsing liquid discharge nozzle 201 to a part of the inclined part 333 of the upper cup 33, more specifically, to a cup rinsing position Zcr in the vertical direction Z as shown in FIG. 11B. By doing so, the cup rinsing liquid flows down along the inclined surface 334 of the inclined part 333 to perform the cup rinsing processing (Step S12d). Upon detecting the passage of a processing time required for the cup rinsing processing on the rotating cup 31, etc., the arithmetic processor 10A gives a supply stop command to the cup rinsing liquid supplier 203 to stop discharge of the cup rinsing liquid.

Subsequently to this, the arithmetic processor 10A gives a rotation stop command to the motor 23 to stop the rotation of the rotating cup 31 (Step S12e). In this way, the cup rinsing processing is finished and a series of the processes is finished. The series of these steps (Step S1 to Step 12) is performed repeatedly.

As described above, in the present embodiment, the cup rinsing liquid is supplied directly from a side of the axis of rotation AX to the rotating cup 31 rotating about the axis of rotation AX. In this way, the cup rinsing processing is performed. This allows the rotating cup 31 to be kept clean, making it possible to effectively prevent the occurrence of particles due to liquid droplets of the processing liquid adhering to the rotating cup 31. Leaving cup contamination due to the processing liquid, particularly due to a chemical liquid unremoved might cause deformation of the rotating cup prepared by a material such as resin. In this regard, performing the cup rinsing processing with appropriate timing suppresses the deformation of the rotating cup 31. Specifically, it is possible to encourage extended life of the rotating cup 31. As a result, running cost can be lowered. Furthermore, such effects can be achieved with the amount of use of the cup rinsing liquid smaller than the amount used in the substrate processing apparatus described in Patent Document 1, thereby contributing to reduction in environmental load.

At the rotating cup 31, the processing liquid is collected at the inclined surface 334 of the inclined part 333 of the upper cup 33. In doing this, centrifugal force generated in response to the cup rotation acts on liquid droplets adhering to the inclined surface 334 of the inclined part 333 of the rotating cup 31. Furthermore, effect is exerted from an airflow resulting from the nitrogen gas, etc. supplied during the bevel processing and flowing radially outward along the upper surface Wf and the lower surface Wb of the substrate W. As a result of these, vector stress applied downward along the inclined surface 334 of the inclined part 333 acts on the liquid droplets. Furthermore, the cup rinsing liquid is supplied to the inclined part 333 and flows downward along the inclined part 333. As a result, the processing liquid can be removed efficiently from the rotating cup 31.

A liquid landing position of the cup rinsing liquid on the inclined part 333, namely, the cup rinsing position Zer is set higher in the vertical direction Z than the height position Zw where liquid droplets of the processing liquid scattered from the rotating substrate W are collected. This allows the liquid droplets of the processing liquid collected at the inclined part 333 to be removed entirely by rinsing with the cup rinsing liquid flowing down along the inclined surface 334 of the inclined part 333, thereby achieving excellent cup rinsing effect.

As shown in FIG. 11B, in the present embodiment, the cup rinsing processing is performed with the disk part 42 of the upper surface protecting/heating mechanism 4 close to the inclined part 333 of the upper cup 33. This may cause bouncing of part of the cup rinsing liquid having landed on the inclined part 333. By considering this point, in the present embodiment, the cup rinsing position Zer is set lower than the position of the upper surface of the disk part 42 of the upper surface protecting/heating mechanism 4, namely, lower than the height position Z42. This makes it possible to effectively prevent liquid droplets of the cup rinsing liquid having bounced at the cup rinsing position Zcr from adhering to the upper surface of the disk part 42.

While heat released from the upper surface protecting/heating mechanism 4 heats the upper cup 33 as well as the substrate W, the cup rinsing liquid at a normal temperature is supplied to the upper cup 33 to thereby reduce the temperature of the upper cup 33. As a result, it is possible to enhance heat resistance of the upper cup 33 and suppress deformation of the upper cup 33.

In the present embodiment, the discharge port 202 has a diameter larger than the diameter of the discharge port 511 of the upper surface processing nozzle 51F. This achieves the following effects. In the present embodiment, in order to suppress bouncing of the cup rinsing liquid at the cup rinsing position Zcr, a discharge speed of the cup rinsing liquid is set lower than a discharge speed of the processing liquid. Meanwhile, the discharge port 202 is set to have a comparatively large diameter, as described above. Thus, even though the discharge speed of the cup rinsing liquid is moderated, it is still possible to gain the amount of supply of the cup rinsing liquid to be supplied to the cup rinsing position Zer per unit time. Specifically, the cup rinsing liquid sufficient for the cup rinsing processing can be supplied while bouncing of the cup rinsing liquid is suppressed at the cup rinsing position Zcr. As a result, it is possible to perform the cup rinsing processing favorably while reducing adverse effect due to bouncing of the cup rinsing liquid.

As shown in FIG. 11B, the discharge direction D33 of the cup rinsing liquid is inclined toward the rotation direction Dr of the upper cup 33 with respect to the radial direction AR. This allows liquid droplets of the cup rinsing liquid having bounced at the cup rinsing position Zcr to be effectively prevented from returning to and adhering to the rinsing liquid discharge nozzle 201, as described above. As a result, it is possible to perform the cup rinsing processing continuously using the rinsing liquid discharge nozzle 201 to reduce a frequency of maintenance on the rinsing liquid discharge nozzle 201 or the rotating cup 31, thereby enhancing the operating efficiency of the apparatus.

In the present embodiment, the rinsing liquid discharge nozzle 201 and the upper surface processing nozzle 51F are held collectively by the nozzle holder 53 to form the nozzle head 56. The nozzle head 56 is moved by the nozzle mover 54 to the cup rinsing position (see FIG. 11B). In this way, the rinsing liquid discharge nozzle 201 is position at a position suitable for the cup rinsing processing with high accuracy. Thus, the cup rinsing liquid can be supplied to an intended position on the upper cup 33 to allow the cup rinsing processing to be performed favorably.

As described above, in the present embodiment, the control unit 10 corresponds to one example of a “controller” of the present invention. The cup rinsing position Zcr corresponds to one example of a “discharge destination of the cup rinsing liquid” of the present invention. The height position Zw corresponds to one example of a “height position of the upper surface of the substrate” of the present invention. The rinsing liquid discharge nozzle 201 corresponds to one example of an “upper surface rinsing nozzle” of the present invention. The inclined surface 334 corresponds to one example of an “inner peripheral surface of the rotating cup” of the present invention.

In the above-described first embodiment, the cup rinsing liquid is discharged toward the cup rinsing position Zer at the inclined surface 334 from above a substrate holding height in the vertical direction Z where the substrate W is held on the spin chuck 21. Simultaneously with this, the cup rinsing liquid may be discharged toward the cup rinsing position Zer in such a manner as to discharge the cup rinsing liquid toward the inclined surface 334 from below the substrate holding height (second embodiment).

FIG. 14 is a diagram schematically showing the configuration and operation of the second embodiment of the substrate processing apparatus according to the present invention. The second embodiment largely differs from the first embodiment in that a rinsing liquid discharge nozzle 204 is provided on the upper surface of the nozzle support 57 (flange part 572) supporting the lower surface processing nozzle 51B. The rinsing liquid discharge nozzle 204 is fixed to the nozzle support 57 while a discharge port 205 thereof for discharging the cup rinsing liquid faces the cup rinsing position Zcr. As the other configuration and operation are the same as those of the first embodiment, they will be given the same signs and descriptions thereof will be omitted.

In the second embodiment, when the arithmetic processor 10A controls the cup rinsing liquid supplier 203 to supply the cup rinsing liquid further to the rinsing liquid discharge nozzle 204 during the cup rinsing processing (Step S12d), the cup rinsing liquid is supplied to the cup rinsing position Zer from the rinsing liquid discharge nozzles 201 and 204 simultaneously. Thus, the cup rinsing liquid is supplied to the inclined part 333 of the upper cup 33 both from obliquely above and from obliquely below. As a result, cup rinsing performance more excellent than that of the first embodiment is achieved.

As described above, in the second embodiment, the rinsing liquid discharge nozzle 204 corresponds to one example of a “lower surface rinsing nozzle” of the present invention.

As the rinsing liquid discharge nozzle of the present invention, the upper surface rinsing nozzle 201 is provided in the first embodiment, and the upper surface rinsing nozzle 201 and the lower surface rinsing nozzle 204 are provided in the second embodiment. In one configuration, however, only the lower surface rinsing nozzle 204 may be provided (third embodiment). In the third embodiment, as the upper surface rinsing nozzle is not used, the nozzle head 56 (=upper surface processing nozzle 51F+nozzle holder 53) can be separated from the inclined part 333 during the cup rinsing processing. This can reduce a likelihood that the cup rinsing liquid reflected on the inclined part 333 will adhere to the upper surface processing nozzle 51F. Furthermore, the rinsing liquid discharge nozzle 204 is simply required to be fixed to the nozzle support 57 in a posture of making the discharge port 205 face the cup rinsing position Zer, thereby facilitating adjustment of the rinsing liquid discharge nozzle 204. Additionally, using the fixedly arranged rinsing liquid discharge nozzle 204 eliminates the need of the step of positioning the rinsing liquid discharge nozzle 201 at the cup rinsing position (Step S12b) in the first embodiment or in the second embodiment. As a result, it is possible to encourage shortening of processing time.

Furthermore, the present invention is not limited to the above-described embodiment and numerous modifications and variations can be added to those described above without departing from the scope of the invention. For example, in the above-described embodiments, the spin chuck 21 and the rotating cup 31 are driven to rotate by the single motor 23. Alternatively, the spin chuck 21 and the rotating cup 31 may be driven to rotate by respective different motors. The present invention is also applicable to such a substrate processing apparatus. Furthermore, in this substrate processing apparatus, it is possible to supply the cup rinsing liquid while rotating only the rotating cup 31 during the cup rinsing processing. As a result, it is possible to reduce power consumption during the cup rinsing processing, making it possible to encourage reduction in environmental load.

In the above-described embodiment, the present invention is applied to a substrate processing apparatus having a raised floor structure in which the substrate processing part SP is installed on the upper surface of the base member 17. Furthermore, in the above-described embodiment, the present invention is applied to a substrate processing apparatus having the rotating cup 31. Further, in the above-described embodiment, the present invention is applied to a substrate processing apparatus having the atmosphere separating mechanism 6, the centering mechanism 8 and the substrate observing mechanism 9. As described in, for example, Patent Document 1, however, the present invention can be applied to the substrate processing apparatus in general which processes the peripheral edge part of the substrate W by supplying a processing liquid to the peripheral edge part of the substrate W in the internal space 12 of the chamber 11.

While the present invention is applied to the substrate processing apparatus which performs the bevel processing as one example of “substrate processing,” the present invention is applicable to a substrate processing apparatus in general which performs the substrate processing on the substrate by supplying the processing liquid to the rotating substrate.

Although the invention has been described by way of the specific embodiments above, this description is not intended to be interpreted in a limited sense. By referring to the description of the invention, various modifications of the disclosed embodiments will become apparent to a person skilled in this art similarly to other embodiments of the invention. Hence, appended claims are thought to include these modifications and embodiments without departing from the true scope of the invention.

### Industrial Applicability

This invention is applicable to substrate processing techniques in general, where substrates are processed with a processing liquid.

### REFERENCE SIGNS LIST

1 . . . substrate processing apparatus (substrate processing system)
2A . . . substrate holder
2B . . . rotating mechanism
3 . . . scattering preventing mechanism
4 . . . upper surface protecting/heating mechanism
5 . . . processing mechanism
10 . . . control unit (controller)
10A . . . arithmetic processor
21 . . . spin chuck
31 . . . rotating cup
32 . . . lower cup
33 . . . upper cup
42 . . . disk part
51B . . . lower surface processing nozzles (processing liquid discharge nozzle)
51F . . . upper surface processing nozzle (processing liquid discharge nozzle)
52 . . . processing liquid supplier
53 . . . nozzle holder
54 . . . nozzle mover
56 . . . nozzle head
201 . . . (upper surface) rinsing liquid discharge nozzle
202 . . . discharge port (of upper surface rinsing liquid discharge nozzle)
203 . . . cup rinsing liquid supplier
204 . . . (lower surface) rinsing liquid discharge nozzle
205 . . . discharge port (of lower surface rinsing liquid discharge nozzle)
333 . . . inclined part (of upper cup)
334 . . . inclined surface
AR . . . radial direction
AX . . . axis of rotation
D33 . . . discharge direction
Dr . . . rotation direction
Ws . . . peripheral edge part (of substrate)
Z . . . vertical direction
Zw . . . height position (of upper surface of substrate)

1. A substrate processing apparatus, comprising:
a holder provided rotatably about an axis of rotation extending in a vertical direction while holding a substrate;
a cup provided rotatably about the axis of rotation while surrounding an outer periphery of the substrate held by the holder;
a rotating mechanism configured to rotate the holder and the cup;
a processing liquid discharge nozzle configured to perform predetermined substrate processing on the substrate by supplying a processing liquid to the substrate held by the rotating holder;
a rinsing liquid discharge nozzle configured to perform cup rinsing processing of removing the processing liquid from the cup by supplying a cup rinsing liquid from a side of the axis of rotation directly to the cup where the processing liquid scattered from the substrate is collected; and
a controller configured to control the rotating mechanism and the rinsing liquid discharge nozzle in such a manner as to supply the cup rinsing liquid to the rotating cup while rotating the cup after implementation of the substrate processing.

2. The substrate processing apparatus according to claim 1, wherein
the cup has a lower cup to be rotated about the axis of rotation in response to receipt of a rotational driving force applied from the rotating mechanism, and an upper cup configured to collect liquid droplets of the processing liquid scattered from the substrate while rotating about the axis of rotation integrally with the lower cup by being coupled to the lower cup,
the upper cup has a coupled part positioned above the lower cup and coupled to the lower cup, and an inclined part inclined upwardly of a peripheral edge part of the substrate from the coupled part, and
the liquid droplets are collected at the inclined part.

3. The substrate processing apparatus according to claim 2, wherein
the rinsing liquid discharge nozzle has a rinsing liquid discharge nozzle configured to discharge the cup rinsing liquid toward the inclined part, and
a discharge destination of the cup rinsing liquid from the rinsing liquid discharge nozzle is a cup rinsing position higher in the vertical direction than a height position of an upper surface of the substrate held by the substrate holder.

4. The substrate processing apparatus according to claim 3, further comprising:
a disk part incorporating a heater that is configured to heat a central part of the upper surface of the substrate other than the peripheral edge part supplied with the processing liquid, the disk part being located above the substrate, wherein
the cup rinsing position is lower in the vertical direction than an upper surface of the disk part.

5. The substrate processing apparatus according to claim 3, wherein
a discharge direction of the cup rinsing liquid from the rinsing liquid discharge nozzle is inclined toward a rotation direction of the cup with respect to a radial direction extending from the axis of rotation toward the rinsing liquid discharge nozzle within a horizontal plane.

6. The substrate processing apparatus according to claim 3, wherein
the processing liquid discharge nozzle is an upper surface processing nozzle that is configured to discharge the processing liquid toward a peripheral edge part of the upper surface of the substrate from above the substrate held by the holder, and
the rinsing liquid discharge nozzle is an upper surface rinsing nozzle that is configured to discharge the cup rinsing liquid toward an inner peripheral surface of the cup from above a substrate holding height in the vertical direction where the substrate is held by the holder.

7. The substrate processing apparatus according to claim 6, comprising:
a nozzle holder configured to collectively hold the upper surface processing nozzle and the upper surface rinsing nozzle arranged close to each other; and
a nozzle mover configured to move the nozzle holder to a substrate processing position for implementation of the substrate processing or to a cup rinsing position for implementation of the cup rinsing processing, wherein
the controller is configured to control the processing liquid discharge nozzle and the rinsing liquid discharge nozzle in such a manner as to discharge the processing liquid from the upper surface processing nozzle while stopping discharge of the cup rinsing liquid from the upper surface rinsing nozzle when the nozzle holder moves to the substrate processing position, and to discharge the cup rinsing liquid from the upper surface rinsing nozzle while stopping discharge of the processing liquid the upper surface processing nozzle when the nozzle holder moves to the cup rinsing position.

8. The substrate processing apparatus according to claim 3, wherein
the processing liquid discharge nozzle is a lower surface processing nozzle that is configured to discharge the processing liquid toward a peripheral edge part of a lower surface of the substrate from below the substrate held by the holder, and
the rinsing liquid discharge nozzle is a lower surface rinsing nozzle that is configured to discharge the cup rinsing liquid toward an inner peripheral surface of the cup from below a substrate holding height in the vertical direction where the substrate is held by the holder.

9. The substrate processing apparatus according to claim 3, wherein
the processing liquid discharge nozzle has an upper surface processing nozzle and a lower surface processing nozzle, the upper surface processing nozzle being configured to discharge the processing liquid toward a peripheral edge part of the upper surface of the substrate from above the substrate held by the holder, the lower surface processing nozzle being configured to discharge the processing liquid toward a peripheral edge part of a lower surface of the substrate from below the substrate held by the holder, and
the rinsing liquid discharge nozzle has an upper surface rinsing nozzle and a lower surface rinsing nozzle, the upper surface rinsing nozzle being configured to supply the cup rinsing liquid to an inner peripheral surface of the cup by discharging the cup rinsing liquid toward the inner peripheral surface from above a substrate holding height in the vertical direction where the substrate is held by the holder, the lower surface rinsing nozzle being configured to supply the cup rinsing liquid to the inner peripheral surface of the cup by discharging the cup rinsing liquid toward the inner peripheral surface from below the substrate holding height.

10. A substrate processing method, comprising:
performing predetermined substrate processing on a substrate configured to rotate about an axis of rotation extending in a vertical direction with a processing liquid by supplying the processing liquid to the substrate while surrounding an outer periphery of the substrate with a cup, and collecting the processing liquid scattered from the substrate in the cup; and
removing the processing liquid from the cup by supplying a cup rinsing liquid from a side of the axis of rotation directly to the cup while rotating the cup about the axis of rotation with the processing liquid collected in the cup.
